(19) United States
(12) Patent Application Publication
(10) Pub. No.: US 2025/0273250 A1
(43) Pub. Date: Aug. 28, 2025

(54) BIFURCATED ACCESS LINE CONTACTS

(71) Applicant: Micron Technology, Inc., Boise, ID (US)

(72) Inventor: David A. Daycock, Boise, ID (US)

(21) Appl. No.: 19/041,082

(22) Filed: Jan. 30, 2025

Related U.S. Application Data
(60) Provisional application No. 63/557,897, filed on Feb. 26, 2024.

(51) Int. Cl. G11C 5/06; H10B 12/00; H10D 30/00; H10D 30/01; H10D 30/43; H10D 62/10; H10D 64/66

(52) U.S. Cl. CPC G11C 5/063; H10B 12/05; H10B 12/488; H10D 30/014; H10D 30/019; H10D 30/43; H10D 30/501; H10D 62/121; H10D 64/665

(57) ABSTRACT

Systems, methods, and apparatus are provided for bifurcated access line contacts. Horizontally oriented access devices each have a first source/drain region and a second source drain region separated by channel regions. Gates opposing the channel regions formed fully around every surface of the channel region as gate all around (GAA) structures separated from channel regions by gate dielectrics. Horizontally oriented storage nodes can be electrically coupled to the second source/drain regions of the horizontally oriented access devices. A staircase structure at each level on a periphery of the array of vertically stacked memory cells and a plurality of separate vertical connections each connected to a different one of a plurality of horizontally oriented access lines formed with the GAA structures on each level of the array.

### PRIORITY INFORMATION

The application claims the benefit of U.S. Provisional Application No. 63/557,897, filed on Feb. 26, 2024, the contents of which are incorporated herein by reference.

### TECHNICAL FIELD

The present disclosure relates generally to memory devices, and more particularly, to bifurcated access line contacts.

### BACKGROUND

Memory is often implemented in electronic systems, such as computers, cell phones, hand-held devices, etc. There are many different types of memory, including volatile and non-volatile memory. Volatile memory may require power to maintain its data and may include random-access memory (RAM), dynamic random-access memory (DRAM), static random-access memory (SRAM), and synchronous dynamic random-access memory (SDRAM). Non-volatile memory may provide persistent data by retaining stored data when not powered and may include NAND flash memory, NOR flash memory, nitride read only memory (NROM), phase-change memory (e.g., phase-change random access memory), resistive memory (e.g., resistive random-access memory), cross-point memory, ferroelectric random-access memory (FeRAM), or the like.

As design rules shrink, less semiconductor space is available to fabricate memory, including DRAM arrays. A respective memory cell for DRAM may include an access device, e.g., transistor, having a first and a second source/drain region separated by a channel region. A gate may oppose the channel region and be separated therefrom by a gate dielectric. An access line, such as a word line, is electrically connected to the gate of the DRAM memory cell. A DRAM memory cell can include a storage node, such as a capacitor cell, coupled by the access device to a sense line, such as a digit line. The access device can be activated (e.g., to select the cell) by an access line coupled to the access device. The capacitor can store a charge corresponding to a data value of a respective memory cell (e.g., a logic “1” or “0”).

### BRIEF DESCRIPTION OF THE DRAWINGS

FIG. 1A is a schematic illustration of an array of memory cells in a vertical three dimensional (3D) memory in accordance with a number of embodiments of the present disclosure.

FIG. 1B is a perspective view illustrating a portion of a horizontal access devices in vertical three dimensional (3D) memory in accordance with a number of embodiments of the present disclosure.

FIG. 2 illustrates a portion of a horizontal access devices in vertical three dimensional (3D) memory in accordance with a number of embodiments of the present disclosure.

FIG. 3 is a schematic illustration of a vertical three dimensional memory in accordance with a number of embodiments of the present disclosure.

FIG. 4 is a perspective view illustrating horizontal access devices in accordance with a number of embodiments of the present disclosure.

FIG. 5 is a cross-sectional view of a vertical stack in vertical three dimensional (3D) memory in accordance with a number of embodiments of the present disclosure.

FIGS. 6A to 6B illustrate an example method, at one stage of a semiconductor fabrication process, for forming bifurcated access line contacts in vertical three dimensional (3D) memory, in accordance with a number of embodiments of the present disclosure.

FIGS. 7A to 7D illustrate an example method, at another stage of a semiconductor fabrication process, for forming bifurcated access line contacts in vertical three dimensional (3D) memory, in accordance with a number of embodiments of the present disclosure.

FIGS. 8A to 8B illustrate an example method, at another stage of a semiconductor fabrication process, for forming bifurcated access line contacts in vertical three dimensional (3D) memory, in accordance with a number of embodiments of the present disclosure.

FIG. 9 illustrates an example method, at another stage of a semiconductor fabrication process, for forming bifurcated access line contacts in vertical three dimensional (3D) memory, in accordance with a number of embodiments of the present disclosure.

FIGS. 10A to 10H illustrate an example method, at another stage of a semiconductor fabrication process, for forming bifurcated access line contacts in vertical three dimensional (3D) memory, in accordance with a number of embodiments of the present disclosure.

FIG. 11 is a block diagram of an apparatus in the form of a computing system including a memory device in accordance with a number of embodiments of the present disclosure.

### DETAILED DESCRIPTION

Embodiments of the present disclosure describe forming bifurcated access line contacts. A vertically oriented sense line (e.g., digit line) is formed with horizontally oriented access devices and horizontally oriented access lines in an array of vertically stacked memory cells. The horizontally oriented access devices are integrated with horizontally oriented access lines (e.g., word lines) having first source/drain regions and second source drain regions separated by channel regions and integrated with vertically oriented digit lines. In vertically stacked memory array structures, the conductive material that is deposited to form horizontally oriented access lines can cascade down multiple levels of the vertical stack. This can cause the horizontally oriented access lines of the multiple levels of the vertical stack to all be connected through the continuous conductive material that has cascaded down the multiple levels of the vertical stack in a periphery of the vertical stack, wherein the periphery of the vertical stack includes a staircase structure or a termination of the access device pattern. As used herein, the term “continuous conductive material” can refer to a conductive material that deposited on multiple levels of a vertical stack, wherein the conductive material is deposited such that there are no gaps in the conductive material that would electrically isolate any portion of the conductive material from another portion of the conductive material.

When the horizontally oriented access lines of the different levels of the vertical stack are connected in this way, a memory device may not be able to activate any of the horizontally oriented access lines individually. This can result in the horizontally oriented access lines being shorted to each other when any of the horizontally oriented access lines are activated. As used herein, activating a horizontally oriented access line can involve providing current to a horizontally oriented access line such that a memory cell coupled to that horizontally oriented access line can be selected.

However, embodiments of the present disclosure can separate the connected horizontally oriented access lines. The connected horizontally oriented access lines can be separated by an etching process in which spaced, vertical openings are formed in a mask material deposited over the different levels of the staircase structure of the vertical stack. Another etch can be performed that removes a portion of the access line material and the access line contact material at each level of the staircase structure. Depositions and further etching can be performed in which a conductive material is deposited to form access line contacts at every level of the staircase structure. This can result in the horizontally oriented access lines no longer being connected and the access lines contacts being bifurcated such that the access line contacts are coupled to the now separated horizontally oriented access lines of the different levels of the staircase structure. As used herein, the term “bifurcated” refers to access line contacts that have been separated into two separate parts.

Forming bifurcated access line contacts as described above provides the benefit of allowing the horizontally oriented access line of each level of the staircase structure to be activated individually. Each access line contact can be coupled to a power source such that the power source can provide current and/or voltage to each horizontally oriented access line individually. This improves over previous approaches because this prevents the horizontally oriented access lines from being shorted to each other when a horizontally oriented access line on a level of the staircase structure is activated.

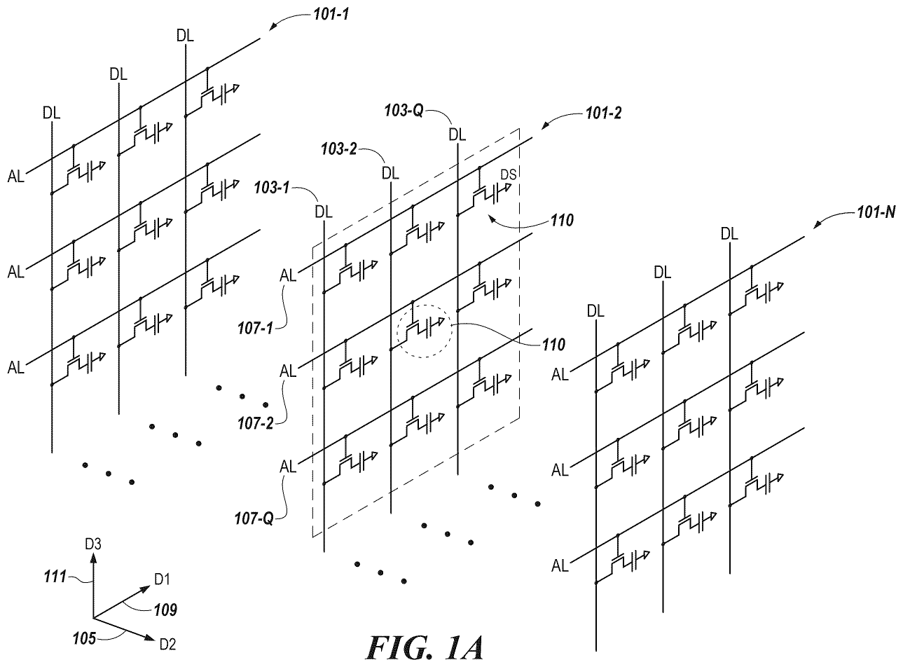

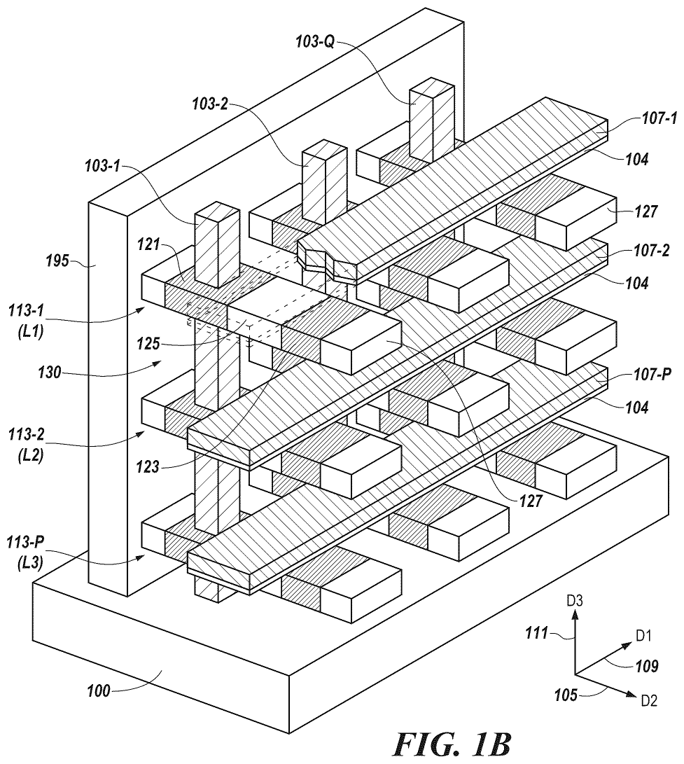

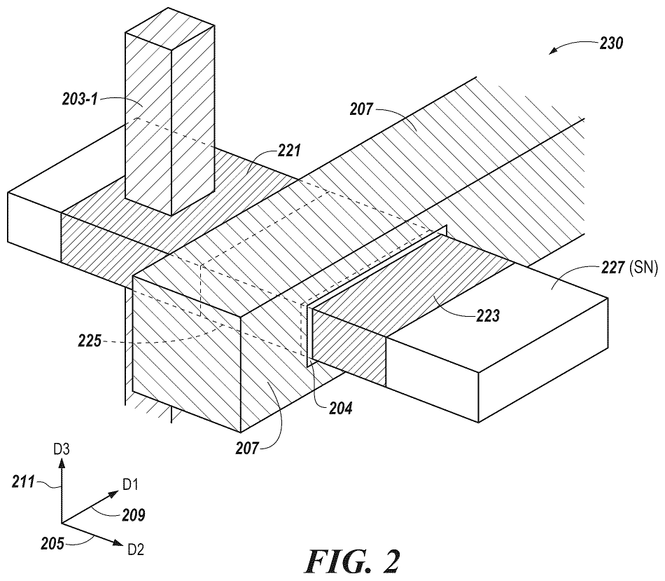

The figures herein follow a numbering convention in which the first digit or digits correspond to the figure number of the drawing and the remaining digits identify an element or component in the drawing. Similar elements or components between different figures may be identified by the use of similar digits. For example, reference numeral 103 may reference element “03” in FIG. 1A, and a similar element may be referenced as 203 in FIG. 2. Multiple analogous elements within one figure may be referenced with a reference numeral followed by a hyphen and another numeral or a letter. For example, 107-1 may reference element 107-1 in FIG. 1A and 107-2 may reference element 107-2, which may be analogous to element 107-1. Such analogous elements may be generally referenced without the hyphen and extra numeral or letter. For example, elements 107-1 and 107-2 or other analogous elements may be generally referenced as 107.

FIG. 1A is a schematic illustration of an array of memory cells in a vertical three dimensional (3D) memory in accordance with a number of embodiments of the present disclosure. FIG. 1A illustrates that a cell array may have a plurality of sub cell arrays 101-1, 101-2, . . . , 101-N. The sub cell arrays 101-1, 101-2, . . . , 101-N may be arranged along a second direction (D2) 105. Each of the sub cell arrays, e.g., sub cell array 101-2, may include a plurality of access lines 107-1, 107-2, . . . , 107-Q (which also may be referred to a word lines). Also, each of the sub cell arrays, e.g., sub cell array 101-2, may include a plurality of digit lines 103-1, 103-2, . . . , 103-Q (which also may be referred to as bit lines, data lines, or sense lines). In FIG. 1A, the access lines 107-1, 107-2, . . . , 107-Q are illustrated extending in a first direction (D1) 109 and the digit lines 103-1, 103-2, . . . , 103-Q are illustrated extending in a third direction (D3) 111. According to embodiments, the first direction (D1) 109 and the second direction (D2) 105 may be considered in a horizontal (“X-Y”) plane. The third direction (D3) 111 may be considered in a vertical (“Z”) plane. Hence, according to embodiments described herein, the digit lines 103-1, 103-2, . . . , 103-Q are extending in a vertical direction, e.g., third direction (D3) 111.

A memory cell, e.g., 110, may include an access device, e.g., access transistor, and a storage node located at an intersection of each access line 107-1, 107-2, . . . , 107-Q and each digit line 103-1, 103-2, . . . , 103-Q. Memory cells may be written to, or read from, using the access lines 107-1, 107-2, . . . , 107-Q and digit lines 103-1, 103-2, . . . , 103-Q. The access lines 107-1, 107-2, . . . , 107-Q may conductively interconnect memory cells along horizontal rows of each sub cell array 101-, 101-2, . . . , 101-N, and the digit lines 103-1, 103-2, . . . , 103-Q may conductively interconnect memory cells along vertical columns of each sub cell array 101-1, 101-2, . . . , 101-N. One memory cell, e.g., 110, may be located between one access line, e.g., 107-2, and one digit line, e.g., 103-2. Each memory cell may be uniquely addressed through a combination of an access line 107-1, 107-2, . . . , 107-Q and a digit line 103-1, 103-2, . . . , 103-Q.

The access lines 107-1, 107-2, . . . , 107-P may be or include conducting patterns (e.g., metal lines) disposed on and spaced apart from a substrate. The access lines 107-1, 107-2, . . . , 107-Q may extend in a first direction (D1) 109. The access lines 107-1, 107-2, . . . , 107-Q in one sub cell array, e.g., 101-2, may be spaced apart from each other in a vertical direction, e.g., in a third direction (D3) 111.

The digit lines 103-1, 103-2, . . . , 103-Q may be or include conductive patterns (e.g., metal lines) extending in a vertical direction with respect to the substrate, e.g., in a third direction (D3) 111. The digit lines in one sub cell array, e.g., 101-2, may be spaced apart from each other in the first direction (D1) 109.

A gate of a memory cell, e.g., memory cell 110, may be connected to an access line, e.g., 107-2, and a first conductive node, e.g., a first source/drain region, of an access device, e.g., transistor, of the memory cell 110 may be connected to a digit line, e.g., 103-2. Each of the memory cells, e.g., memory cell 110, may be connected to a storage node, e.g., capacitor. A second conductive node, e.g., second source/drain region, of the access device, e.g., transistor, of the memory cell 110 may be connected to the storage node, e.g., capacitor. While first and second source/drain region references are used herein to denote two separate and distinct source/drain regions, it is not intended that the source/drain region referred to as the “first” and/or “second” source/drain regions have some unique meaning. It is intended only that one of the source/drain regions is connected to a digit line, e.g., 103-2, and the other may be connected to a storage node.

FIG. 1B illustrates a perspective view showing a three dimensional (3D) semiconductor memory device, e.g., a portion of a sub cell array 101-2 shown in FIG. 1A as a vertically oriented stack of memory cells in an array, according to some embodiments of the present disclosure.

As shown in FIG. 1B, a substrate 100 may have formed thereon one of the plurality of sub cell arrays, e.g., 101-2, described in connection with FIG. 1A. For example, the substrate 100 may be or include a silicon substrate, a germanium substrate, or a silicon-germanium substrate, etc. Embodiments, however, are not limited to these examples.

As shown in the example embodiment of FIG. 1B, the substrate 100 may have fabricated thereon a vertically oriented stack of memory cells, e.g., memory cell 110 in FIG. 1A, extending in a vertical direction, e.g., third direction (D3) 111. According to some embodiments the vertically oriented stack of memory cells may be fabricated such that each memory cell, e.g., memory cell 110 in FIG. 1A, is formed on plurality of vertical levels, e.g., a first level (L1), a second level (L2), and a third level (L3). The repeating, vertical levels, L1, L2, and L3, may be arranged, e.g., “stacked”, a vertical direction, e.g., third direction (D3) 111 shown in FIG. 1A, and may be separated from the substrate 100 by an insulator material. Each of the repeating, vertical levels, L1, L2, and L3 may include a plurality of discrete components, e.g., regions, to the horizontally oriented access devices 130, e.g., transistors, and storage nodes, e.g., capacitors, including access line 107-1, 107-2, . . . , 107-Q connections and digit line 103-1, 103-2, . . . , 103-Q connections. The plurality of discrete components to the horizontally oriented access devices 130, e.g., transistors, may be formed in a plurality of iterations of vertically, repeating layers within each level and may extend horizontally in the second direction (D2) 105, analogous to second direction (D2) 105 shown in FIG. 1A.

The plurality of discrete components to the laterally oriented access devices 130, e.g., transistors, may include a first source/drain region 121 and a second source/drain region 123 separated by a channel region 125, extending laterally in the second direction (D2) 105, and formed in a body of the access devices. In some embodiments, the channel region 125 may include silicon, germanium, silicon-germanium, and/or indium gallium zinc oxide (IGZO). In some embodiments, the first and the second source/drain regions, 121 and 123, can include an n-type dopant region formed in a p-type doped body to the access device to form an n-type conductivity transistor. In some embodiments, the first and the second source/drain regions, 121 and 123, may include a p-type dopant formed within an n-type doped body to the access device to form a p-type conductivity transistor. By way of example, and not by way of limitation, the n-type dopant may include phosphorous (P) atoms and the p-type dopant may include atoms of boron (B) formed in an oppositely doped body region of polysilicon semiconductor material. Embodiments, however, are not limited to these examples.

The storage node 127, e.g., capacitor, may be connected to one respective end of the access device. As shown in FIG. 1B, the storage node 127, e.g., capacitor, may be connected to the second source/drain region 123 of the access device. The storage node may be or include memory elements capable of storing data. Each of the storage nodes may be a memory element using one of a capacitor, a magnetic tunnel junction pattern, and/or a variable resistance body which includes a phase change material, etc. Embodiments, however, are not limited to these examples. In some embodiments, the storage node associated with each access device of a unit cell, e.g., memory cell 110 in FIG. 1A, may similarly extend in the second direction (D2) 105, analogous to second direction (D2) 105 shown in FIG. 1A.

As shown in FIG. 1B a plurality of horizontally oriented access lines 107-1, 107-2, . . . , 107-Q extend in the first direction (D1) 109, analogous to the first direction (D1) 109 in FIG. 1A. The plurality of horizontally oriented access lines 107-1, 107-2, . . . , 107-Q may be analogous to the access lines 107-1, 107-2, . . . , 107-Q shown in FIG. 1A. The plurality of horizontally oriented access lines 107-1, 107-2, . . . , 107-Q may be arranged, e.g., “stacked”, along the third direction (D3) 111. The plurality of horizontally oriented access lines 107-1, 107-2, . . . , 107-Q may include a conductive material. For example, the conductive material may include one or more of a doped semiconductor, e.g., doped silicon, doped germanium, etc., a conductive metal nitride, e.g., titanium nitride, tantalum nitride, etc., a metal, e.g., tungsten (W), titanium (Ti), tantalum (Ta), ruthenium (Ru), cobalt (Co), molybdenum (Mo), etc., and/or a metal-semiconductor compound, e.g., tungsten silicide, cobalt silicide, titanium silicide, etc. Embodiments, however, are not limited to these examples.

Among each of the vertical levels, (L1) 113-1, (L2) 113-2, and (L3) 113-P, the horizontally oriented memory cells, e.g., memory cell 110 in FIG. 1A, may be spaced apart from one another horizontally in the first direction (D1) 109. However, the plurality of discrete components to the horizontally oriented access devices 130, e.g., first source/drain region 121 and second source/drain region 123 separated by a channel region 125, extending laterally in the second direction (D2) 105, and the plurality of horizontally oriented access lines 107-1, 107-2, . . . , 107-Q extending laterally in the first direction (D1) 109, may be formed within different vertical layers within each level. For example, the plurality of horizontally oriented access lines 107-1, 107-2, . . . , 107-Q, extending in the first direction (D1) 109, may be formed on a top surface opposing and electrically coupled to the channel regions 125, separated therefrom by a gate dielectric, and orthogonal to horizontally oriented access devices 130, e.g., transistors, extending in laterally in the second direction (D2) 105. In some embodiments, the plurality of horizontally oriented access lines 107-1, 107-2, . . . , 107-Q, extending in the first direction (D1) 109 are formed in a higher vertical layer, farther from the substrate 100, within a level, e.g., within level (L1), than a layer in which the discrete components, e.g., first source/drain region 121 and second source/drain region 123 separated by a channel region 125, of the horizontally oriented access device are formed.

As shown in the example embodiment of FIG. 1B, the digit lines, 103-1, 103-2, . . . , 103-Q, extend in a vertical direction with respect to the substrate 100, e.g., in a third direction (D3) 111. Further, as shown in FIG. 1B, the digit lines, 103-1, 103-2, . . . , 103-Q, in one sub cell array, e.g., sub cell array 101-2 in FIG. 1A, may be spaced apart from each other in the first direction (D1) 109. The digit lines, 103-1, 103-2, . . . , 103-Q, may be provided, extending vertically relative to the substrate 100 in the third direction (D3) 111 in vertical alignment with source/drain regions to serve as first source/drain regions 121 or, as shown, be vertically adjacent first source/drain regions 121 for each of the horizontally oriented access devices 130, e.g., transistors, extending laterally in the second direction (D2) 105, but adjacent to each other on a level, e.g., first level (L1), in the first direction (D1) 109. Each of the digit lines, 103-1, 103-2, . . . , 103-Q, may vertically extend, in the third direction (D3), on sidewalls adjacent first source/drain regions 121 of respective ones of the plurality of horizontally oriented access devices 130, e.g., transistors, that are vertically stacked. In some embodiments, the plurality of vertically oriented digit lines 103-1, 103-2, . . . , 103-Q, extending in the third direction (D3) 111, may be connected to side surfaces of the first source/drain regions 121 directly and/or through additional contacts including metal silicides.

For example, a first one of the vertically extending digit lines, e.g., 103-1, may be adjacent a sidewall of a first source/drain region 121 to a first one of the horizontally oriented access devices 130, e.g., transistors, in the first level (L1) 113-1, a sidewall of a first source/drain region 121 of a first one of the horizontally oriented access devices 130, e.g., transistors, in the second level (L2) 113-2, and a sidewall of a first source/drain region 121 a first one of the horizontally oriented access devices 130, e.g., transistors, in the third level (L3) 113-P, etc. Similarly, a second one of the vertically extending digit lines, e.g., 103-2, may be adjacent a sidewall to a first source/drain region 121 of a second one of the horizontally oriented access devices 130, e.g., transistors, in the first level (L1) 113-1, spaced apart from the first one of horizontally oriented access devices 130, e.g., transistors, in the first level (L1) 113-1 in the first direction (D1) 109. And the second one of the vertically extending digit lines, e.g., 103-2, may be adjacent a sidewall of a first source/drain region 121 of a second one of the laterally oriented access devices 130, e.g., transistors, in the second level (L2) 113-2, and a sidewall of a first source/drain region 121 of a second one of the horizontally oriented access devices 130, e.g., transistors, in the third level (L3) 113-P, etc. Embodiments are not limited to a particular number of levels.

The vertically extending digit lines, 103-1, 103-2, . . . , 103-Q, may include a conductive material, such as, for example, one of a doped semiconductor material, a conductive metal nitride, metal, and/or a metal-semiconductor compound. The digit lines, 103-1, 103-2, . . . , 103-Q, may correspond to digit lines (DL) described in connection with FIG. 1A.

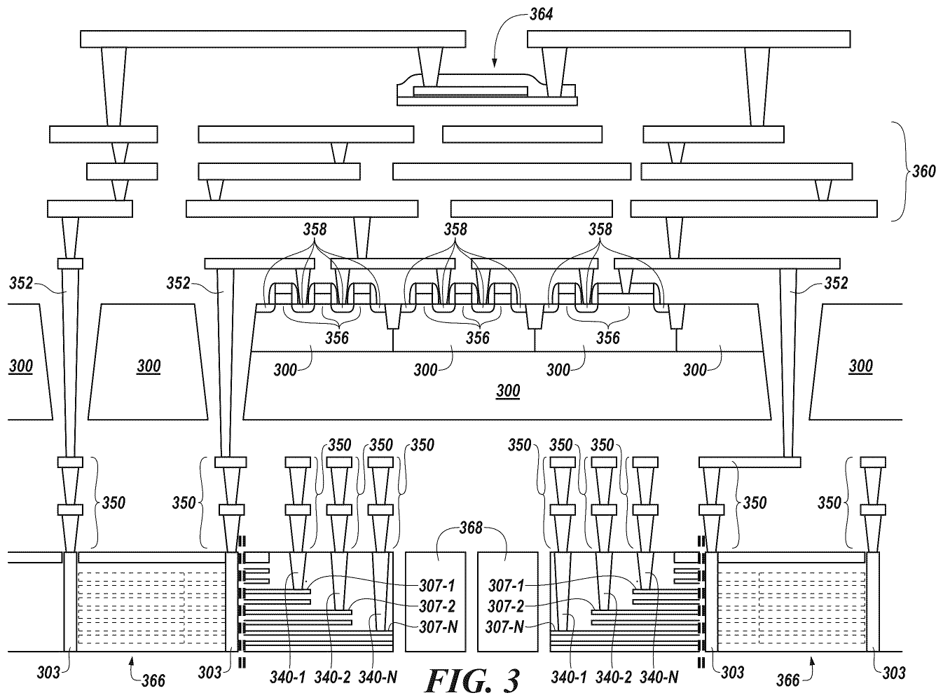

As shown in the example embodiment of FIG. 1B, a conductive body contact may be formed extending in the first direction (D1) 109 along an end surface of the horizontally oriented access devices 130, e.g., transistors, in each level (L1) 113-1, (L2) 113-2, and (L3) 113-P above the substrate 100. The body contact 196 may be connected to a body (as shown by 336 in FIG. 3) e.g., body region, of the horizontally oriented access devices 130, e.g., transistors, in each memory cell, e.g., memory cell 110 in FIG. 1A. The body contact may include a conductive material such as, for example, one of a doped semiconductor material, a conductive metal nitride, metal, and/or a metal-semiconductor compound.

Although not shown in FIG. 1B, an insulating material may fill other spaces in the vertically stacked array of memory cells. For example, the insulating material may include one or more of a silicon oxide material, a silicon nitride material, and/or a silicon oxynitride material, etc. Embodiments, however, are not limited to these examples.

FIG. 2 illustrates a portion of a horizontal access device in vertical three-dimensional (3D) memory in accordance with a number of embodiments of the present disclosure. FIG. 2 illustrates in more detail a unit cell, e.g., memory cell 110 in FIG. 1, of the vertically stacked array of memory cells, e.g., within a sub cell array 101-2 in FIG. 1, according to some embodiments of the present disclosure. As shown in FIG. 2, the first and the second source/drain regions, 221 and 223, may be impurity doped regions to the laterally oriented access devices 230, e.g., transistors. The first and the second source/drain regions may be separated by a channel 225 formed in a body of semiconductor material, e.g., body region of the horizontally oriented access devices 230, e.g., transistors. The first and the second source/drain regions, 221 and 223, may be formed from an n-type or p-type dopant doped in the body region. However, embodiments are not so limited.

For example, for an n-type conductivity transistor construction the body region of the laterally oriented access devices 230, e.g., transistors, may be formed of a low doped p-type (p−) semiconductor material. In one embodiment, the body region and the channel 225 separating the first and the second source/drain regions, 221 and 223, may include a low doped, p-type (e.g., low dopant concentration (p−)) polysilicon (Si) material consisting of boron (B) atoms as an impurity dopant to the polycrystalline silicon. The first and the second source/drain regions, 221 and 223, may also comprise a metal, and/or metal composite materials containing ruthenium (Ru), molybdenum (Mo), nickel (Ni), titanium (Ti), copper (Cu), a highly doped degenerate semiconductor material, and/or at least one of indium oxide (In2O3), or indium tin oxide (In2—xSnxO3), formed using an atomic layer deposition process, etc. Embodiments, however, are not limited to these examples. As used herein, a degenerate semiconductor material is intended to mean a semiconductor material, such as polysilicon, containing a high level of doping with significant interaction between dopants, e.g., phosphorus (P), boron (B), etc. Non-degenerate semiconductors, by contrast, contain moderate levels of doping, where the dopant atoms are well separated from each other in the semiconductor host lattice with negligible interaction.

In this example, the first and the second source/drain regions, 221 and 223, may include a high dopant concentration, n-type conductivity impurity (e.g., high dopant (n+)) doped in the first and the second source/drain regions, 221 and 223. In some embodiments, the high dopant, n-type conductivity first and second drain regions 221 and 223 may include a high concentration of phosphorus (P) atoms deposited therein. Embodiments, however, are not limited to this example. In other embodiments, the horizontally oriented access devices 230, e.g., transistors, may be of a p-type conductivity construction in which case the impurity, e.g., dopant, conductivity types would be reversed.

As shown in FIG. 2, the first and the second source/drain regions, 221 and 223, may be impurity doped regions to the laterally oriented access devices 230, e.g., transistors. The first and the second source/drain regions may be separated by a channel 225 formed in a body of semiconductor material, e.g., body region, of the horizontally oriented access devices 230, e.g., transistors. The first and the second source/drain regions, 221 and 223, may be formed from an n-type or p-type dopant doped in the body region. However, embodiments are not so limited.

The first source/drain region 221 may occupy an upper portion in the body of the laterally oriented access devices 230, e.g., transistors. For example, the first source/drain region 221 may have a bottom surface within the body of the horizontally oriented access device 230 which is located higher, vertically in the third direction (D3) 211, than a bottom surface of the body of the laterally, horizontally oriented access device 230. As such, the laterally, horizontally oriented transistor 230 may have a body portion which is below the first source/drain region 221 and is in electrical contact with the body contact. Further, as shown in the example embodiment of FIG. 2, an access line, e.g., 207, analogous to the access lines 107-1, 107-2, . . . , 107-Q shown in FIG. 1, may disposed on a top surface opposing and coupled to a channel region 225, separated therefrom by a gate dielectric 204. The gate dielectric material 204 may include, for example, a high-k dielectric material, a silicon oxide material, a silicon nitride material, a silicon oxynitride material, etc., or a combination thereof. Embodiments are not so limited. For example, in high-k dielectric material examples the gate dielectric material 304 may include one or more of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobite, etc.

As shown in the example embodiment of FIG. 2, a digit line, e.g., 203-1, analogous to the digit lines 103-1, 103-2, . . . , 103-Q in FIG. 1, may be vertically extending in the third direction (D3) 211 adjacent a sidewall of the first source/drain region 221 in the body to the horizontally oriented access devices 230, e.g., transistors horizontally conducting between the first and the second source/drain regions 221 and 223 along the second direction (D2) 205. In this embodiment, the vertically oriented digit line 203-1 is formed symmetrically, in vertical alignment, in electrical contact with the first source/drain region 221. The digit line 203-1 may be formed in contact with an insulator material such that there is no body contact within channel 225.

As shown in the example embodiment of FIG. 2, the digit line 203-1 may be formed symmetrically within the first source/drain region 221 such that the first source/drain region 221 surrounds the digit line 203-1 all around. The first source/drain region 221 may occupy an upper portion in the body of the laterally oriented access devices 230, e.g., transistors. For example, the first source/drain region 221 may have a bottom surface within the body of the horizontally oriented access device 230 which is located higher, vertically in the third direction (D3) 211, than a bottom surface of the body of the laterally, horizontally oriented access device 230. As such, the laterally, horizontally oriented transistor 230 may have a body portion which is below the first source/drain region 321 and is in contact with the body contact. An insulator material may fill the body contact such that the first source/drain region 221 may not be in electrical contact with channel 225. Further, as shown in the example embodiment of FIG. 2, an access line, e.g., 207, analogous to the access lines 107-1, 107-2, . . . , 107-Q shown in FIG. 1, may disposed all around and coupled to a channel region 225, separated therefrom by a gate dielectric 204.

Although the digit line 203-1 is described above as being formed symmetrically within the first source/drain region 221 such that the first source/drain region 221 surrounds the digit line 203-1 all around, embodiments are not so limited. For instance, in some examples, the digit line 203-1 can be formed asymmetrically. In this embodiment, the vertically oriented digit line is formed asymmetrically adjacent in electrical contact with the first source/drain regions 221. The digit line may be formed asymmetrically to reserve room for a body contact in the channel region 225.

FIG. 3 is a schematic illustration of a vertical three dimensional (3D) memory in accordance with a number of embodiments of the present disclosure. FIG. 3 includes horizontally oriented access lines 307-1, 307-2, . . . , 307-N (individually or collectively referred to as horizontally access lines 307), access line contacts 340-1, 340-2, . . . , 340-N (individually or collectively referred to as access line contacts 340), and vertically oriented sense lines 303.

FIG. 3 illustrates different portions of the vertical 3D memory at different vertical heights of the vertical 3D memory. In the portion of the vertical 3D memory at the lowest vertical height shown in FIG. 3, FIG. 3 illustrates a staircase structure in a periphery of the vertical 3D memory that includes horizontally oriented access lines 307. As used herein, the term “periphery of the vertical 3D memory” refers to an area at an edge of the vertical 3D memory. For example, in FIG. 3, the periphery of the vertical 3D memory can refer to the portion of the vertical 3D memory that includes an area of a structure within the vertical 3D memory that is adjacent a vertical opening that separates a portion of the vertical 3D from a different portion of the vertical 3D memory. For example, the horizontally oriented access lines 307 are in a portion of the vertical 3D memory (e.g., the periphery) that is adjacent a vertical opening that separates this portion of the vertical 3D memory from vertical pillars 368.

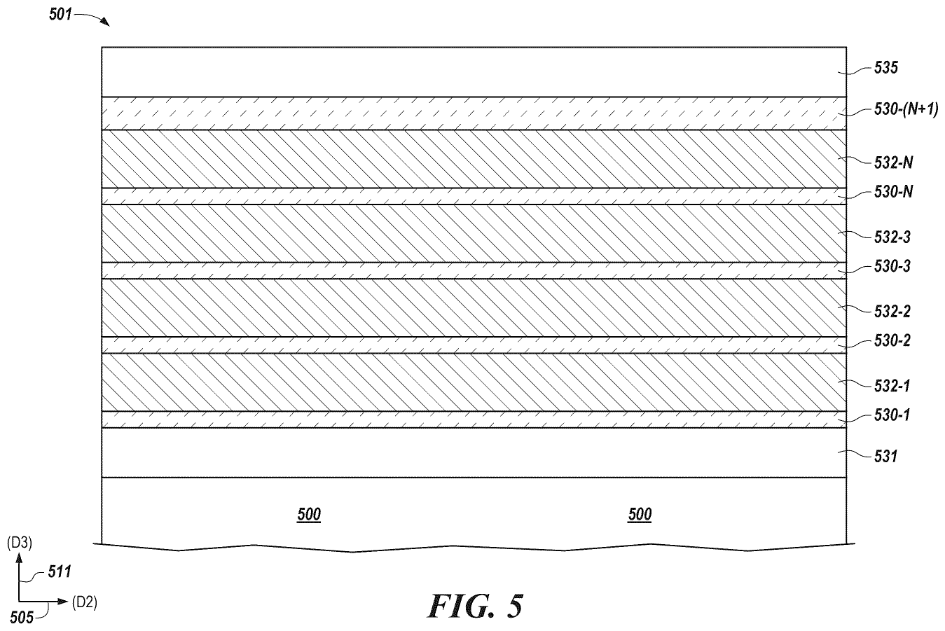

FIG. 3 further illustrates access line contacts 340 coupled to the access lines 307. The access line contacts 340 can be formed as described in FIGS. 10A-10H. In some embodiments, the access line contacts 340 can be coupled to conductive lines 350. In some embodiments, conductive lines 350 can be coupled to a power source that can supply power to the access lines 307 through the access line contacts 340. Portions 366 of the vertical 3D memory can include dielectric materials and conductive materials as described in FIG. 9 and layers of silicon material as described in FIG. 5.

At a portion of the vertical 3D memory array that is located at a higher vertical height than the previously described portion of the vertical 3D memory, FIG. 3 illustrates a plurality of transistors 356 formed on substrate materials 300. The substrate material 300 can be doped to from source/drain regions 358. Conductive lines 352 can be coupled to conductive lines 350 at a lower vertical height than conductive lines 352 and coupled to conductive lines 360 that are at a higher vertical height than conductive lines 352. Further, conductive lines 360 can be coupled to memory component 364.

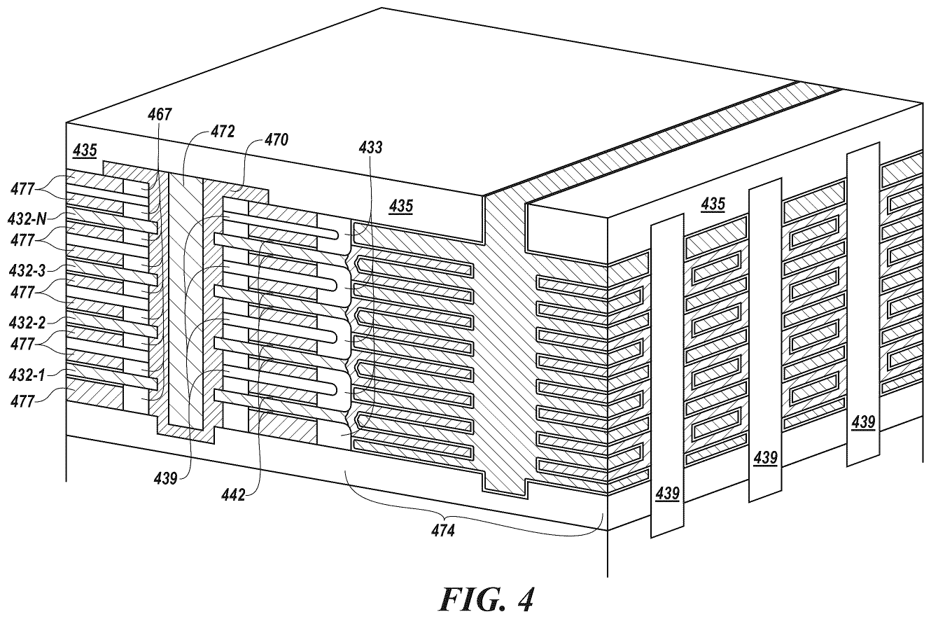

FIG. 4 is a perspective view illustrating horizontal access devices in accordance with a number of embodiments of the present disclosure. FIG. 4 includes first conductive material 477, a silicon (Si) material 432, a photolithographic mask material (e.g., mask material) 435, an interlayer dielectric (ILD) fill material 467, a second conductive material 470, a metal material 472, a first dielectric material 439, a second dielectric material 433, a second interlayer dielectric material 442, and a plurality of storage nodes (e.g., capacitors) 474.

FIG. 4 illustrates a portion of a vertical 3D memory array that is formed in accordance with the process described in FIGS. 5-9 of this application. The horizontal access devices of the vertical 3D memory array can include the second dielectric material 433, the first dielectric material 477, a first dielectric material 439, and ILD fill material 467. In some embodiments, the first dielectric material 439 can be formed using an oxide material. Further, in some embodiments, the first dielectric material 439 and the second dielectric material 433 can be formed from the same material. In other embodiments, a first material can be used to form the first dielectric material 439 and a second material can be used to form the second dielectric material 433, wherein the first material is a different material than the second material.

The access devices can be coupled to the plurality of storage nodes 474. In some embodiments, the plurality of storage nodes 474 can be double-sided capacitors. The access devices can be used to transfer current between the metal material 472 and the plurality of storage nodes 474, which is a stack of multiple storage nodes, such as a stack of storage nodes 227 in FIG. 2.

FIG. 5 is a cross-sectional view of a vertical stack in vertical three dimensional (3D) memory in accordance with a number of embodiments of the present disclosure. In the example embodiment shown in the example of FIG. 5, a method of forming the vertical stack 501 can comprise forming alternating layers of a silicon germanium (SiGe) material, 530-1, 530-2, . . . , 530-N (collectively referred to as silicon germanium (SiGe) 530), and a silicon (Si) material, 532-1, 532-2, . . . , 532-N (collectively referred to as single crystalline silicon (Si) material 532), in repeating iterations to form a vertical stack 501 on a working surface of a semiconductor substrate 500. In some embodiments, the silicon germanium (SiGe) material and the silicon (Si) material can be epitaxially grown.

In one embodiment, the silicon germanium (SiGe) 530 can be deposited to have a thickness, e.g., vertical height in the third direction (D3), in a range of five (5) nanometers to thirty (30) nm. In one embodiment, the silicon (Si) material 532 can be deposited to have a thickness (t2), e.g., vertical height, in a range of thirty (30) nanometers (nm) to sixty (60) nm. Embodiments, however, are not limited to these examples. As shown in FIG. 5, a vertical direction 511 is illustrated as a third direction (D3), e.g., z-direction in an x-y-z coordinate system, analogous to the third direction (D3), among first, second, and third directions, shown in FIGS. 1-3.

In some embodiments, the silicon germanium (SiGe), 530-1, 530-2, . . . , 530-N, may be a mix of silicon and germanium. By way of example, and not by way of limitation, the silicon germanium (SiGe) material 530 may be grown on the substrate material 500. Embodiments are not limited to these examples. In some embodiments, the single crystalline silicon (Si) material, 532-1, 532-2, . . . , 532-N, may comprise a silicon (Si) material in a polycrystalline and/or amorphous state. The single crystalline silicon (Si) material, 532-1, 532-2, . . . , 532-N, may be a low doped, p-type (p−) single crystalline silicon (Si) material. The silicon (Si) material, 532-1, 532-2, . . . , 532-N, may also be formed on the silicon germanium (SiGe) 530. If the silicon germanium (SiGe) 530 was epitaxially grown, the seed is turned to pure silicon after the silicon germanium (SiGe) 530 has been formed.

The repeating iterations of alternating silicon germanium (SiGe), 530-1, 530-2, . . . , 530-N layers and single crystalline silicon (Si) material, 532-1, 532-2, . . . , 532-N layers may be deposited according to a semiconductor fabrication process such as chemical vapor deposition (CVD) in a semiconductor fabrication apparatus. Embodiments, however, are not limited to this example and other suitable semiconductor fabrication techniques may be used to deposit the alternating layers of silicon germanium (SiGe) and single crystalline silicon (Si) material, in repeating iterations to form the vertical stack 501.

The layers may occur in repeating iterations vertically. For example, the stack may include: a first silicon germanium (SiGe) material 530-1, a first single crystalline silicon (Si) material 532-1, a silicon germanium (SiGe) material 530-2, a second single crystalline silicon (Si) material 532-2, a third silicon germanium (SiGe) material 530-3, and a third single crystalline silicon (Si) material 532-3, in further repeating iterations. Embodiments, however, are not limited to this example and more or fewer repeating iterations may be included.

In some embodiments, a bottom portion of the vertical stack 501 can be removed to form a second horizontal opening. The bottom portion of the vertical stack 501 can include a layer of silicon germanium (SiGe) material 530 that is closer to the substrate 500 than other layers of silicon germanium (SiGe) material 530, a layer of silicon (Si) material 532 that is closer to the substrate 500 than other layers of silicon (Si) material 532, or both. Further, a dielectric material 531 can be deposited to fill the horizontal opening.

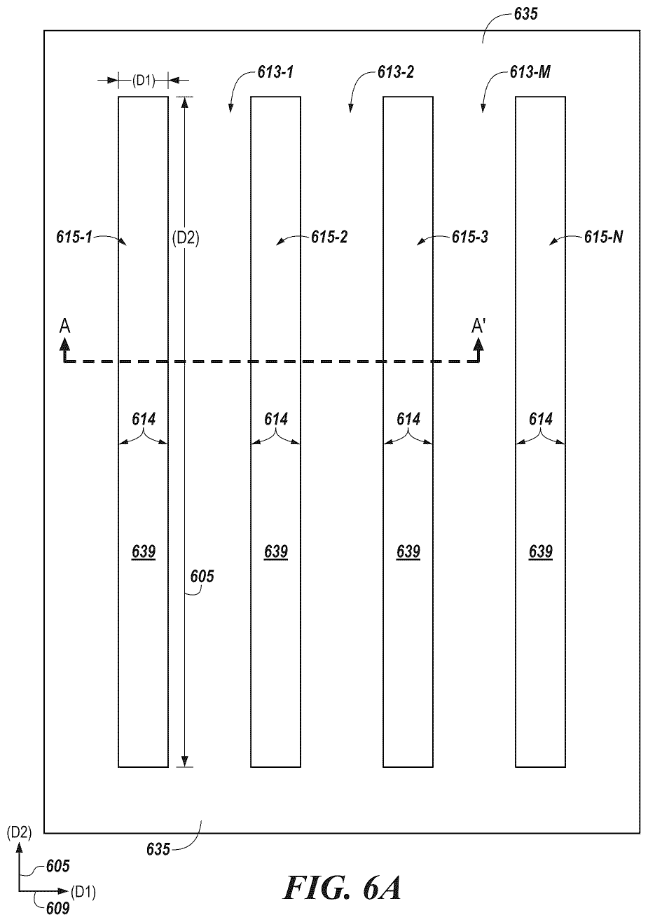

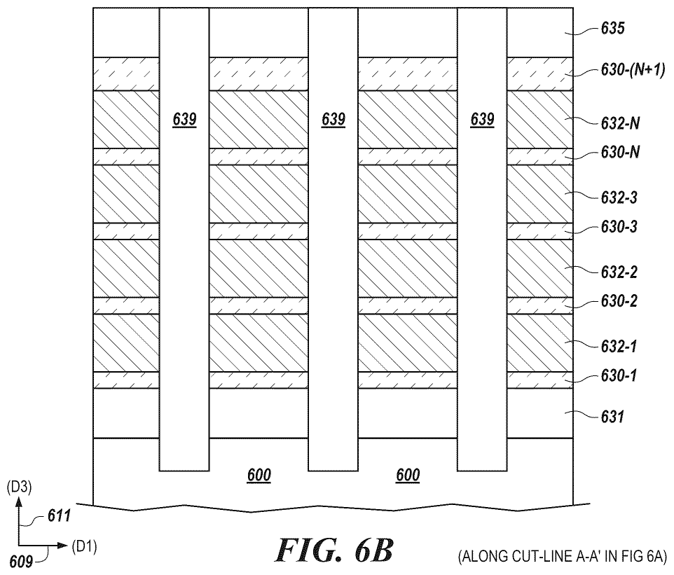

FIG. 6A illustrates an example method, at one stage of a semiconductor fabrication process, for forming bifurcated access line contacts in vertical three dimensional (3D) memory, in accordance with a number of embodiments of the present disclosure. FIG. 6A illustrates a top down view of a semiconductor structure, at a particular point in time, in a semiconductor fabrication process, according to one or more embodiments. In the example embodiment shown in the example of FIG. 6A, the method comprises using an etchant process to form a plurality of vertical openings 615-1, 615-2, 615-3, . . . , 615-N (individually or collectively referred to as vertical openings 615), having a first horizontal direction (D1) 609 and a second horizontal direction (D2) 605, through the vertical stack to the substrate. In one example, as shown in FIG. 6A, the plurality of vertical openings (e.g., fourth vertical openings) 615 are extending predominantly in the second horizontal direction (D2) 605 and may form elongated vertical, pillar columns 613-1, 613-2, . . . , 613-M (collectively and/or independently referred to as vertical, pillar columns 613), with sidewalls 614 in the vertical stack. The plurality of first vertical openings 615 may be formed using photolithographic techniques to pattern a photolithographic mask 635, e.g., to form a hard mask (HM), on the vertical stack prior to etching the plurality of first vertical openings 615. Similar semiconductor process techniques may be used at other points of the semiconductor fabrication process described herein.

The first vertical openings 615 may be filled with a first dielectric material 639. In one example, a spin on dielectric process may be used to fill the first vertical openings 615. In one embodiment, the first dielectric material 639 may be an oxide material. However, embodiments are not so limited.

FIG. 6B is a cross sectional view, taken along cut-line A-A′ in FIG. 6A, showing another view of the semiconductor structure at a particular time in the semiconductor fabrication process for forming bifurcated access line contacts in vertical three dimensional (3D) memory, in accordance with a number of embodiments of the present disclosure. The cross sectional view shown in FIG. 6B shows the repeating iterations of alternating layers of a silicon germanium (SiGe) material 630 and a single crystalline silicon (Si) material 632 on a semiconductor substrate 600 to form the vertical stack, e.g., vertical stack 501 in FIG. 5.

As shown in FIG. 6B, a plurality of vertical openings may be formed through the layers within the vertically stacked memory cells to expose vertical sidewalls in the vertical stack and form elongated vertical pillar columns 613 and then filled with a first dielectric material 639. The first vertical openings 615 may be formed through the repeating iterations of the silicon germanium (SiGe) material 630 and the single crystalline silicon (Si) material 632. As such, the first vertical openings 615 may be formed through a first silicon germanium (SiGe) material 630-1, a first single crystalline silicon (Si) material 632-1, a second silicon germanium (SiGe) material 630-2, a second single crystalline silicon (Si) material 632-2, a third silicon germanium (SiGe) material 630-3, and a third single crystalline silicon (Si) material 632-3. Embodiments, however, are not limited to the vertical opening(s) shown in FIG. 6B. Multiple vertical openings may be formed through the layers of materials. The vertical openings may be formed to expose vertical sidewalls in the vertical stack. The vertical openings may extend in a second direction (D2) 605 to form elongated vertical, pillar columns with vertical sidewalls in the vertical stack and then filled with first dielectric 639.

As shown in FIG. 6B, a first dielectric material 639, such as an oxide or other suitable spin on dielectric (SOD), may be deposited in the first vertical openings 615, using a process such as CVD, to fill the first vertical openings 615. First dielectric material 639 may also be formed from a silicon nitride (Si₃N₄) material. In another example, the first dielectric material 639 may include silicon oxy-nitride (SiOₓN_{y}), and/or combinations thereof. Embodiments are not limited to these examples. The plurality of first vertical openings 615 may be formed using photolithographic techniques to pattern a photolithographic mask 635, e.g., to form a hard mask (HM), on the vertical stack prior to etching the plurality of first vertical openings 615. In one embodiment, hard mask 635 may be deposited over a silicon germanium (SiGe) material 630. Similar semiconductor process techniques may be used at other points of the semiconductor fabrication process described herein.

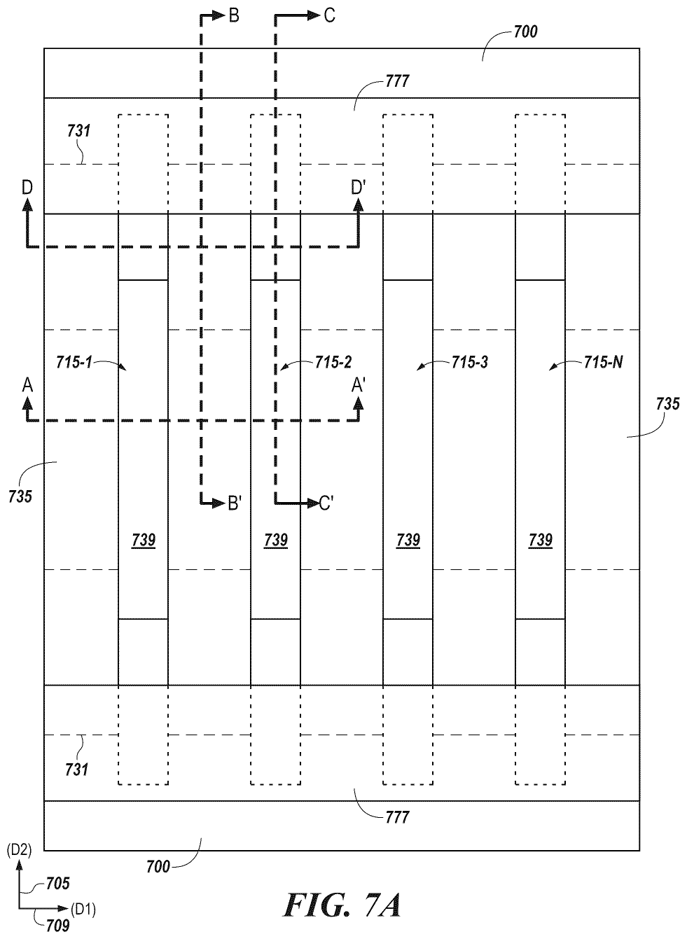

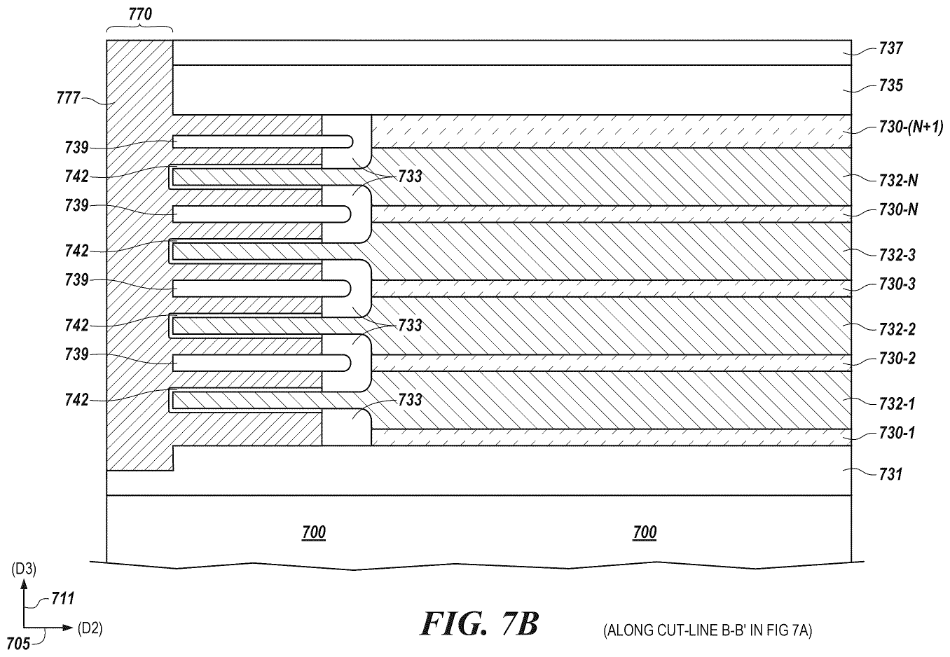

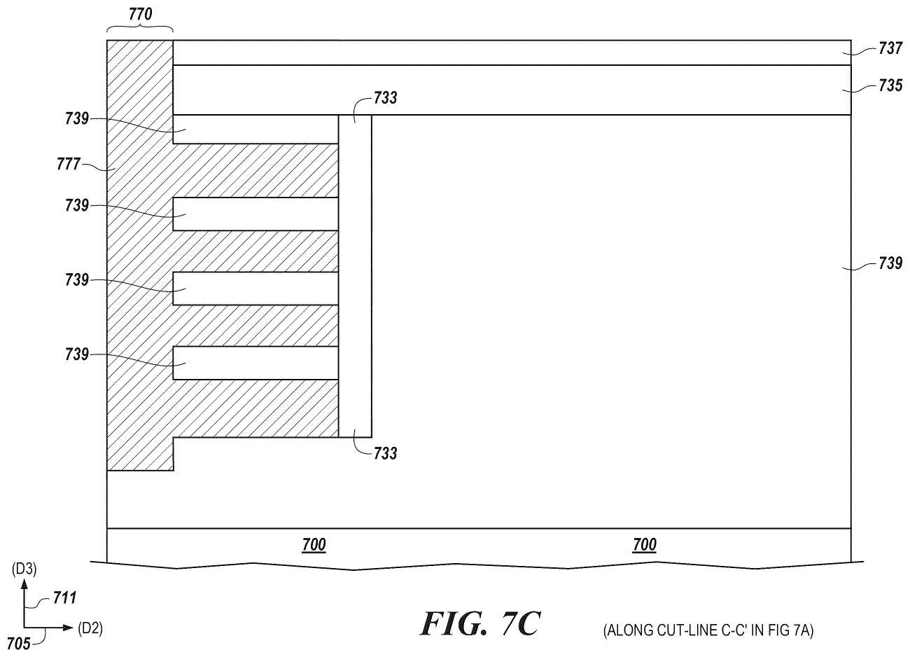

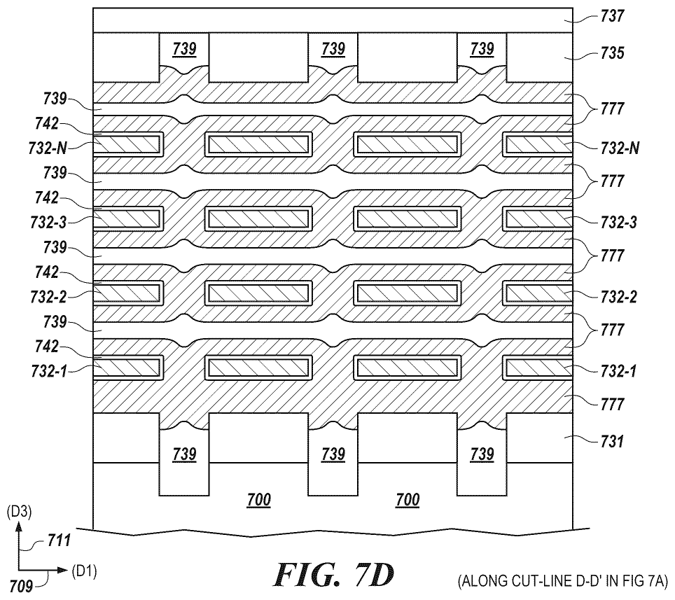

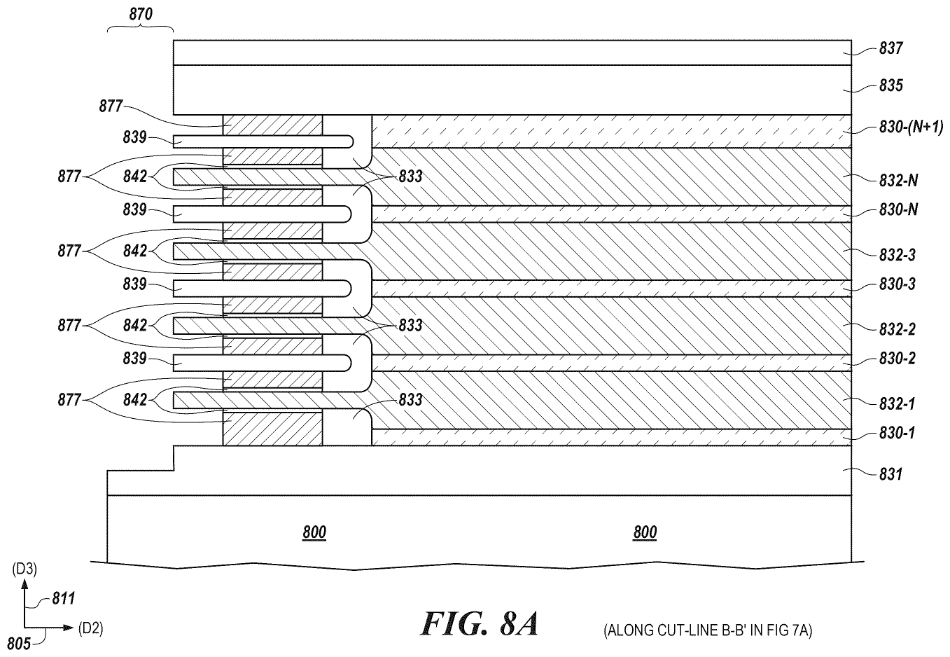

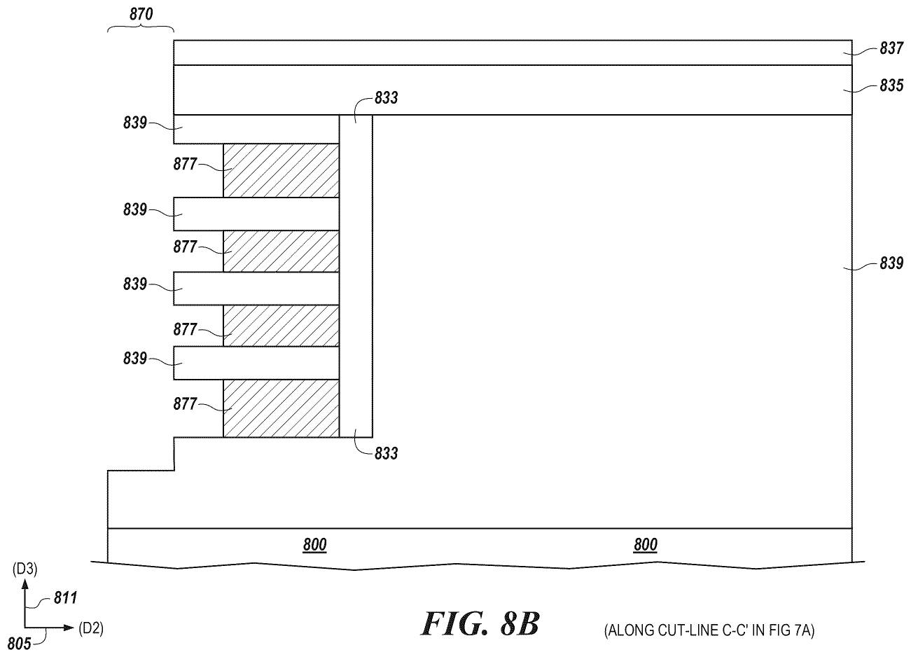

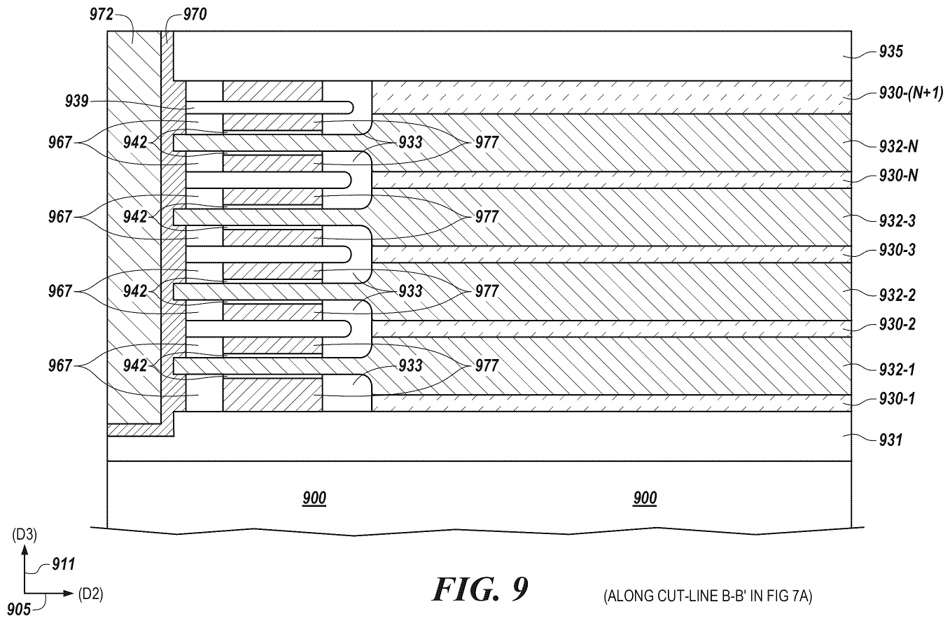

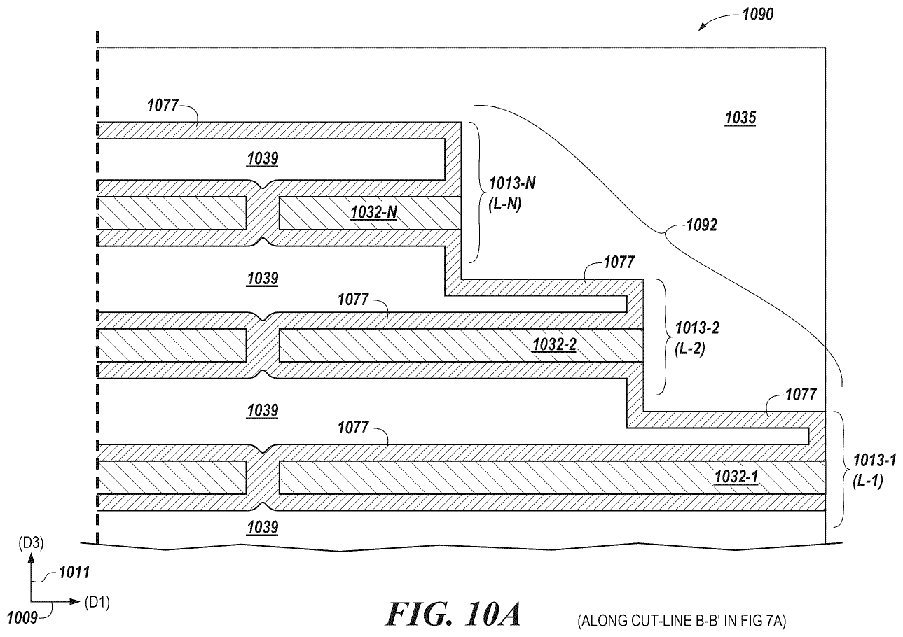

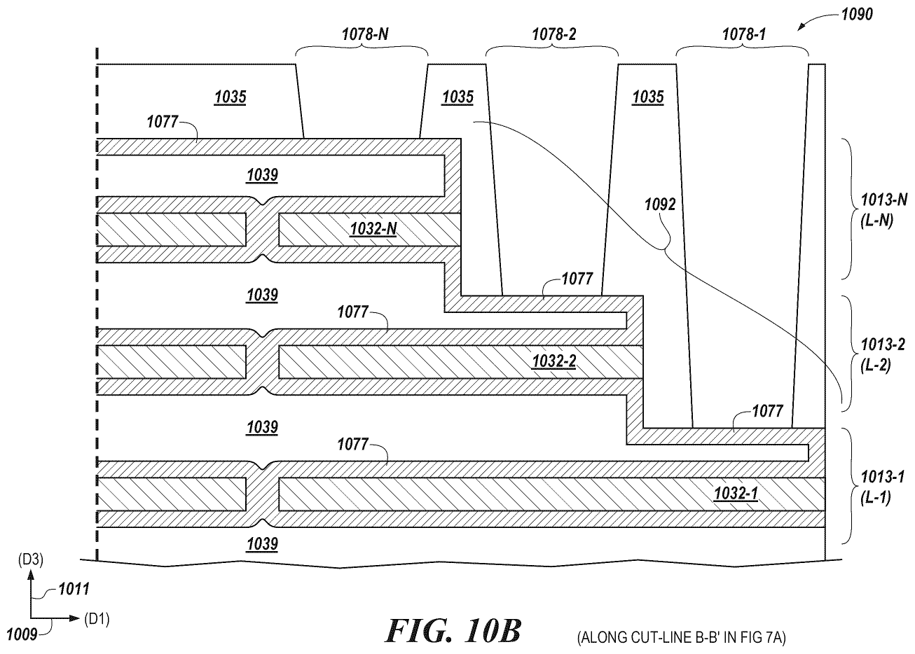

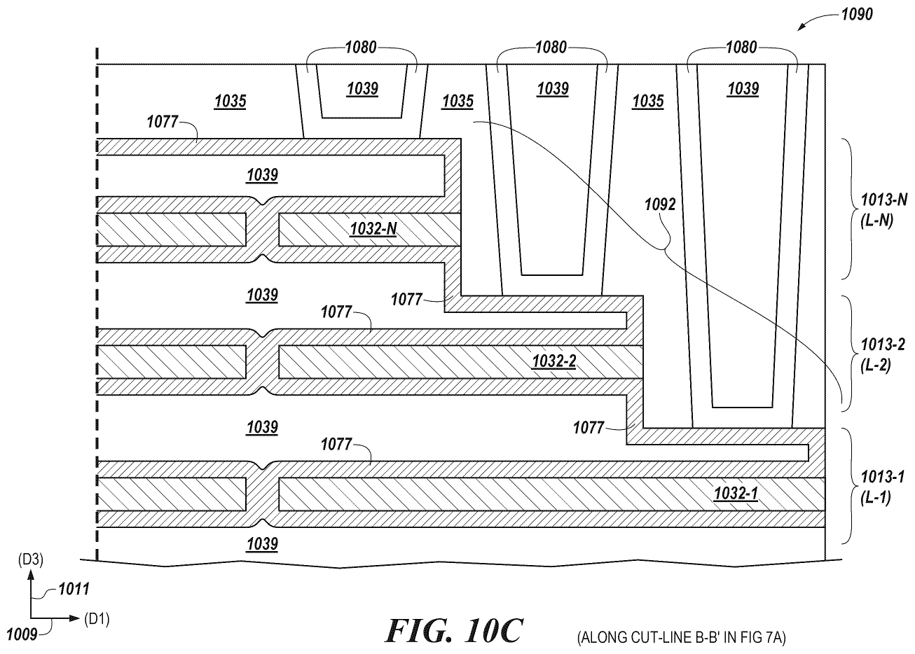

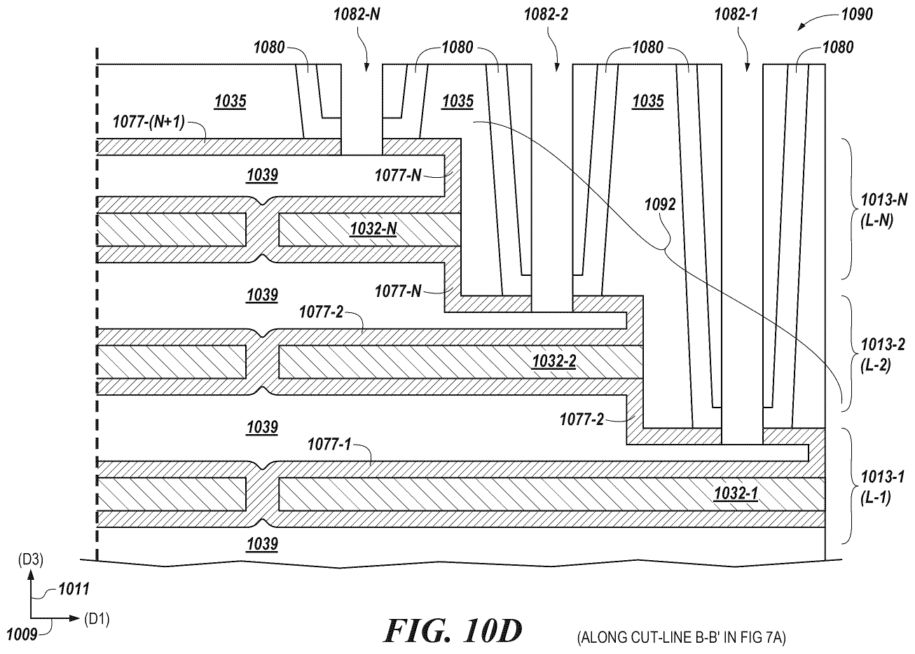

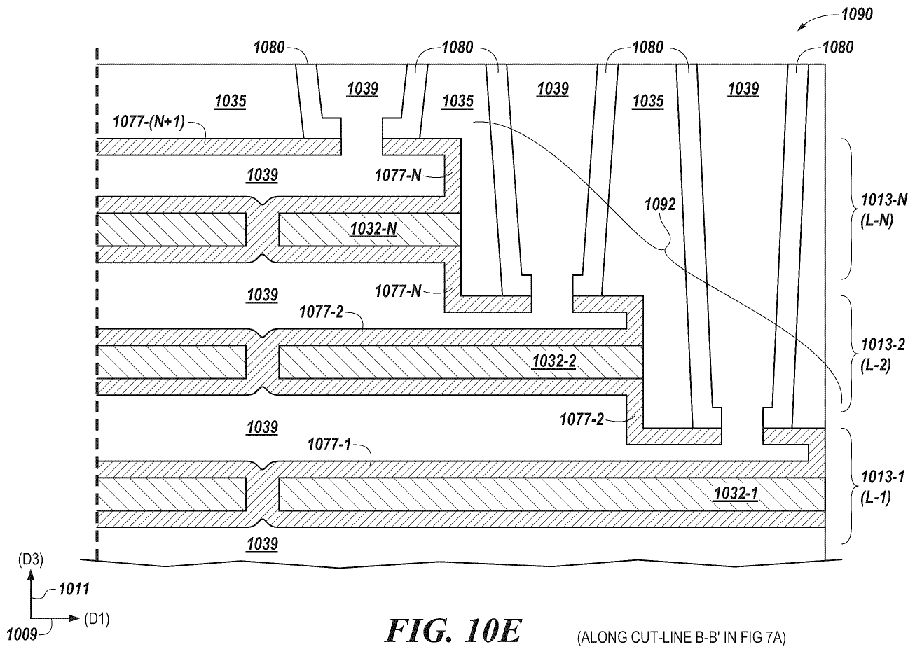

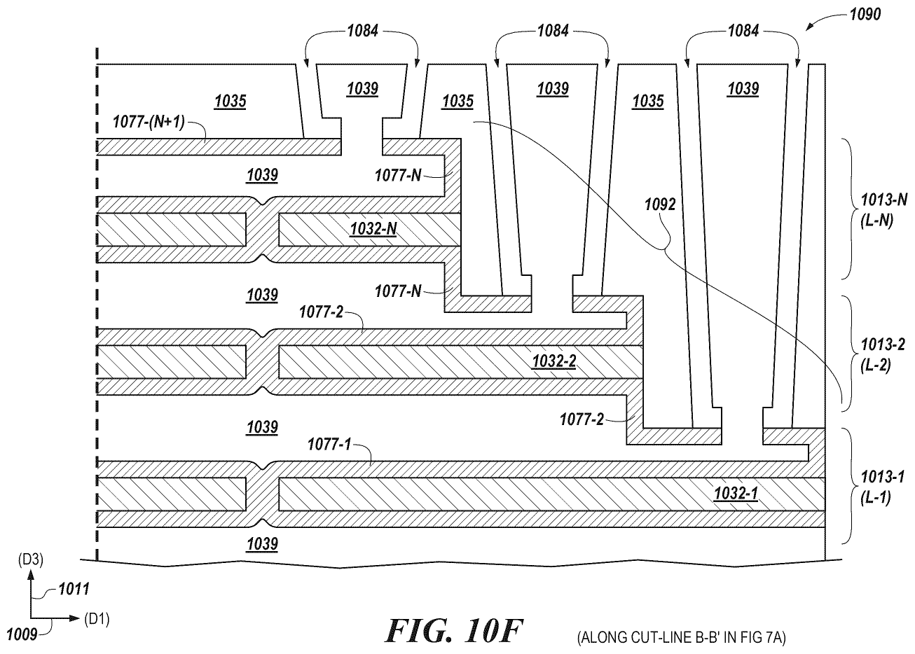

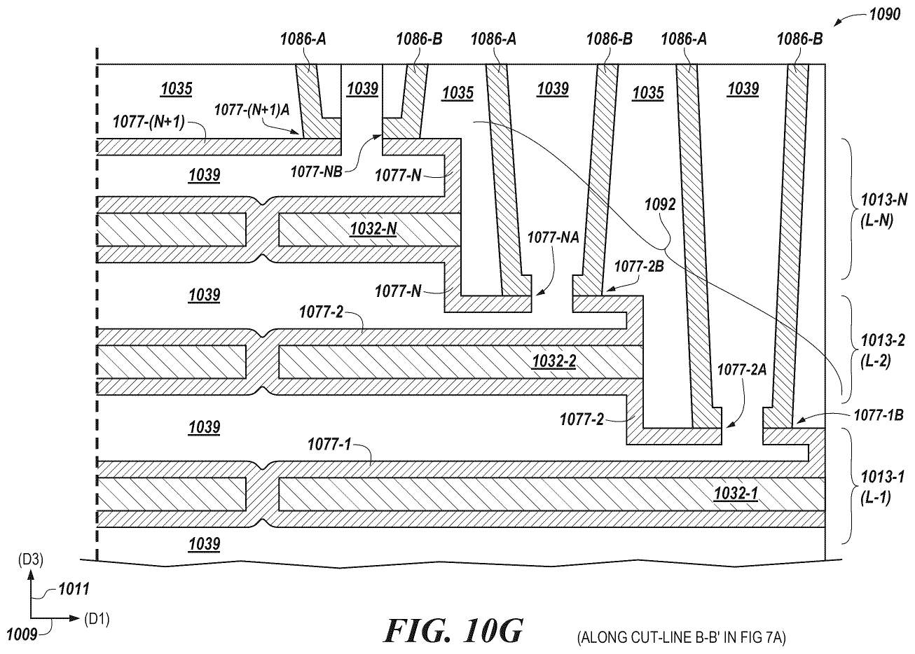

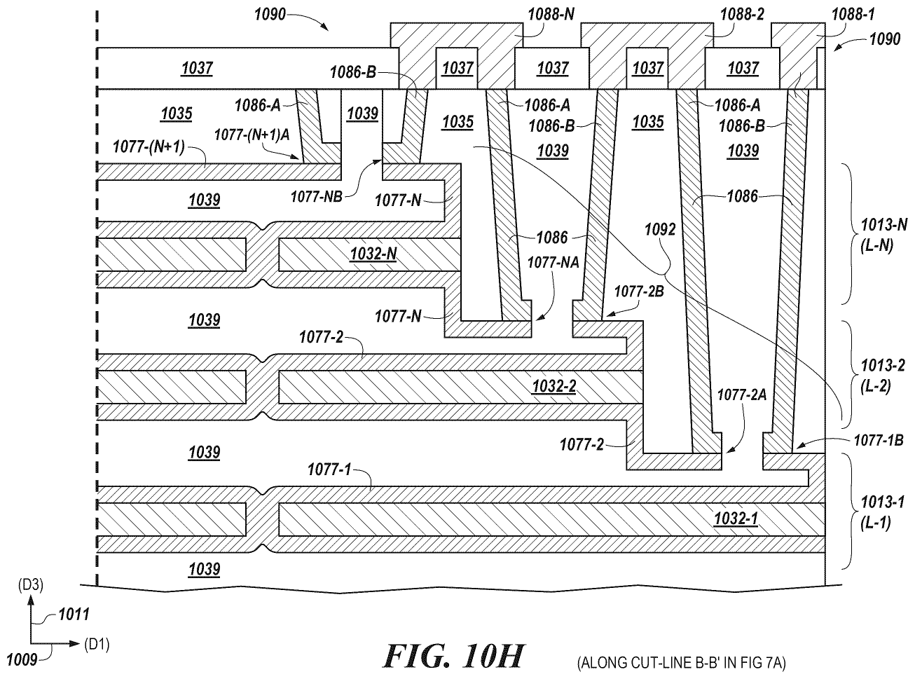

FIG. 7A illustrates an example method, at another stage of a semiconductor fabrication process for forming bifurcated access line contacts in vertical three dimensional (3D) memory, in accordance with a number of embodiments of the present disclosure. FIG. 7A illustrates a top down view of a semiconductor structure, at a particular point in time, in a semiconductor fabrication process, according to one or more embodiments. In the example embodiment of FIG. 7A, the method comprises using a photolithographic process to pattern the photolithographic mask 735. A first conductive material 777 may be deposited above the vertical openings 731. The first conductive material 777 may be deposited in the continuous first horizontal openings to form horizontally oriented access lines opposing channel regions of the single crystalline silicon (Si) material 732.

FIG. 7B illustrates a cross sectional view, taken along cut-line B-B′ in FIG. 7A, showing another view of the semiconductor structure at this particular point in one example semiconductor fabrication process for forming bifurcated access line contacts in vertical three dimensional (3D) memory in accordance with embodiments of the present disclosure. The cross sectional view shown in FIG. 7B is illustrated extending in the second horizontal direction (D2) 705, left and right along the plane of the drawing sheet, along an axis of the repeating iterations of alternating layers of the silicon germanium (SiGe) material 730 and the single crystalline silicon (Si) material 732.

A process of depositing and etching materials is used to form the structure shown in FIG. 7B. In some embodiments, the process of depositing and etching materials can include forming horizontally oriented access devices and horizontally oriented storage nodes (e.g., storage nodes 227 in FIG. 2) at each level of the vertical stack (e.g., vertical stack 501 in FIG. 5) to form an array of vertically stacked memory cells. Each of the horizontally oriented access devices can have first source/drain regions and second source/drain regions separated by channel regions. In some embodiments, gates can be formed fully around every surface of the channel regions as gate all around (GAA) structures on a gate dielectric material. Further, in some embodiments, the second source/drain regions can be coupled to storage nodes.

The semiconductor structure shown in FIG. 7B shows the semiconductor structure after the silicon germanium (SiGe) layers are selectively etched to form a plurality of first horizontal openings a first length from first vertical openings 770. In some embodiments, the second vertical openings 770 can be formed to a depth in a range of 0.5 to one (1) micrometer (μm). Further, in some embodiments, each of the first vertical openings 770 can be formed to have an aspect ratio in a range of 15-20. In some embodiments, the selective etch that forms to plurality of second horizontal openings can also reduce a vertical thickness of the silicon (Si) layers. In some embodiments, a vertical thickness of a portion of each of the silicon (Si) layers can be reduced to a vertical thickness in a range of 100-150 Angstroms (Å).

The process of forming the horizontally oriented access devices can further include conformally depositing a second dielectric material 733 on exposed surfaces in the plurality of first horizontal openings and depositing the first dielectric material 739 to fill the plurality of first horizontal openings. The second dielectric material 739 can be selectively etched from the plurality of first horizontal openings a second length (L2) from the first vertical opening 770. In some embodiments, the second length (L2) can be a length in a range of 130-170 nanometers (nm).

A first conductive material 777 may be deposited in the first horizontal opening on the gate dielectric material 742 after selectively etching the second dielectric material 739. The first conductive material 777 may be deposited around the single crystalline silicon (Si) material 732 such that the first conductive material 777 may have a top portion above the single crystalline silicon (Si) material 732 and a bottom portion below the single crystalline silicon (Si) material to form a gate all around (GAA) gate structure, at a channel of an access device region. The first conductive material 777 may be conformally deposited into vertical openings 770 and fill the continuous horizontal openings up to the unetched portions of the oxide material 742, the first dielectric material 739, and the dielectric material 733. The conductive material 777 may be conformally deposited using a chemical vapor deposition (CVD) process, plasma enhanced CVD (PECVD), atomic layer deposition (ALD), or other suitable deposition process.

In some embodiments, the first conductive material, 777, may comprise one or more of a doped semiconductor, e.g., doped silicon, doped germanium, etc., a conductive metal nitride, e.g., titanium nitride, tantalum nitride, etc., a metal, e.g., tungsten (W), titanium (Ti), tantalum (Ta), ruthenium (Ru), cobalt (Co), molybdenum (Mo), etc., and/or a metal-semiconductor compound, e.g., tungsten silicide, cobalt silicide, titanium silicide, etc., and/or some other combination thereof. The first conductive material 777 entwined with the gate dielectric material may form horizontally oriented access lines opposing a channel region of the single crystalline silicon (Si) material (which also may be referred to a word lines).

FIG. 7C illustrates a cross sectional view, taken along cut-line C-C′ in FIG. 7A, showing another view of the semiconductor structure at this particular point in one example semiconductor fabrication process of an embodiment of the present disclosure. The cross sectional view shown in FIG. 7C is illustrated extending in the second horizontal direction (D2) 705, left and right in the plane of the drawing sheet, along an axis of the repeating iterations of alternating layers of continuous horizontal openings and single crystalline silicon (Si) material 732.

In FIG. 7C, first dielectric material 739 is shown spaced along a second horizontal direction (D2) 705, extending into and out from the plane of the drawings sheet, for a three dimensional (3D) array of vertically oriented memory cells. At the left end of the drawing sheet is shown the repeating iterations of alternating layers of single crystalline silicon (Si) material 732, separated by continuous horizontal openings in a first direction (D1) 709 filled with a first conductive material 777. The first conductive material 777 may be conformally deposited into vertical openings 770 and into the horizontal openings. The first conductive material 777 is formed on the gate dielectric material (e.g., gate dielectric material 742 in FIG. 7B). At the right hand of the drawing sheet, the first dielectric material 739 may be seen, separating access device and storage node regions in the first direction (D1) 709, and having the horizontal opening filled with the second dielectric material 733 and the first dielectric material 739.

FIG. 7D illustrates a cross sectional view, taken along cut-line D-D′ in FIG. 7A, showing another view of the semiconductor structure at this particular point in one example semiconductor fabrication process for forming bifurcated access line contacts in vertical three dimensional (3D) memory, in accordance with a number of embodiments of the present disclosure. The cross sectional view shown in FIG. 7D is illustrated, right to left in the plane of the drawing sheet, extending in the first direction (D1) 709 along an axis of the repeating iterations of alternating layers of first dielectric material 739 and single crystalline silicon (Si) material 732 wrapped with a gate dielectric material 742. The gate dielectric material 742 may be conformally deposited fully around every surface of the single crystalline silicon (Si) material 732, to form gate all around (GAA) gate structures, at the channels of the access device regions. The first conductive material 777 may fill the spaces adjacent the bridged single crystalline silicon (Si) material 732. The single crystalline silicon (Si) material 732 may be surrounded by the first conductive material 777 formed on the gate dielectric material 742. The first conductive material 777 may be conformally deposited fully around every surface of the single crystalline silicon (Si) material 732, to form gate all around (GAA) gate structures, at the channels of the access device regions. In FIG. 7D, the first conductive material, 777 is shown filling in the space in the second horizontal openings left by the etched second dielectric material 733.

FIG. 8A illustrates an example method, at another stage of a semiconductor fabrication process, for forming bifurcated access line contacts in vertical three dimensional (3D) memory, in accordance with a number of embodiments of the present disclosure. The cross sectional view shown in FIG. 8A is illustrated extending in the second horizontal direction (D2) 805, left and right along the plane of the drawing sheet, along an axis of the repeating iterations of alternating layers of the silicon germanium (SiGe) material 830 and the single crystalline silicon (Si) material 832.

A first conductive material 877 was deposited on the gate dielectric material and formed around the single crystalline silicon (Si) material 832, recessed back, to form gate all around (GAA) structure opposing channel regions of the single crystalline silicon (Si) material 832. The first conductive material 877, formed on the gate dielectric material 842, may be recessed and etched away from the vertical opening 870. In some embodiments, the first conductive material 877 may be etched using an atomic layer etching (ALE) process. In some embodiments, the first conductive material 877 may be etched using an isotropic etch process. The first conductive material 877 may be selectively etched leaving the oxide material 842 covering the epitaxially grown, single crystalline silicon (Si) material 832 and the first dielectric material 839 intact. The first conductive material 877 may be selectively etched in the second direction, in the continuous horizontal openings, a third distance (DIST 3) in a range of twenty (20) to fifty (50) nanometers (nm) back from the first vertical opening 870. The first conductive material 877 may be selectively etched around the single crystalline silicon (Si) material 832 back into the continuous horizontal openings extending in the first horizontal direction.

FIG. 8B illustrates an example method, at another stage of a semiconductor fabrication process, for forming bifurcated access line contacts in vertical three dimensional (3D) memory, in accordance with a number of embodiments of the present disclosure. The cross sectional view shown in FIG. 8B is illustrated extending in the second direction (D2) 805, left and right in the plane of the drawing sheet, along an axis of the repeating iterations of alternating layers of the etched first conductive material 877 and single crystalline silicon (Si) material 832.

In FIG. 8B, first dielectric material 839 is shown spaced along a first horizontal direction (D1) 809 extending into and out from the plane of the drawings sheet, for a three dimensional (3D) array of vertically oriented memory cells. At the left end of the drawing sheet is shown the first conductive material 877 formed on the gate dielectric material 842, was etched away from the vertical opening 870. The first conductive material 877, formed on the gate dielectric material 842, is also recessed back in the continuous horizontal openings extending in the first horizontal direction 809. The first conductive material 877 may be selectively etched leaving the oxide material 842 covering the single crystalline silicon (Si) material 832 intact. In some embodiments, the first conductive material 877 may be etched using an atomic layer etching (ALE) process. In some embodiments, the first conductive material 877 may be etched using an isotropic etch process.

FIG. 9 illustrates an example method, at another stage of a semiconductor fabrication process, for forming bifurcated access line contacts in vertical three dimensional (3D) memory, in accordance with a number of embodiments of the present disclosure. The cross sectional view shown in FIG. 9 is illustrated extending in the second horizontal direction (D2) 905, left and right along the plane of the drawing sheet.

FIG. 9 illustrates an example embodiment of a vertical digit line formed by the combination of second conductive material 970 and third conductive material 972 formed within the first vertical openings (e.g., vertical openings 870 in FIG. 8). In one example, a second conductive material 970 may be conformally formed in the vertical openings. The second conductive material 970 may be formed from a conformal deposition of a highly doped polysilicon material 970. In one example, the dopant can include a high concentration n-type dopant. In a further example, the polysilicon may first be deposited and then a high concentration of n-type dopant may be implanted therein from the second conductive material 970. One example of forming the second conductive material 970 includes conformally depositing a highly phosphorus (P) doped (n+-type dopant) poly-silicon germanium (SiGe) material into the first vertical openings for the second conductive material 970.

A third conductive material 972 may be deposited into the first vertical opening on the second conductive material 970 to fill the vertical opening as shown in FIG. 9. In some embodiments, the third conductive material 972 may comprise one or more of a doped semiconductor material, e.g., doped silicon, doped germanium, etc., a conductive metal nitride, e.g., titanium nitride, tantalum nitride, etc., a metal, e.g., tungsten (W), titanium (Ti), tantalum (Ta), ruthenium (Ru), cobalt (Co), molybdenum (Mo), etc., and/or a metal-semiconductor compound, e.g., tungsten silicide, cobalt silicide, titanium silicide, etc., and/or some other combination thereof. The third conductive material 972 coupled to the second conductive material 970 may be formed vertically adjacent first source/drain regions to horizontal access devices to form vertical digit lines.

FIG. 10A illustrates an example method, at another stage of a semiconductor fabrication process, for forming bifurcated access line contacts in vertical three dimensional (3D) memory, in accordance with a number of embodiments of the present disclosure. FIG. 10A illustrates multiple levels of horizontally oriented access lines 1077 extending in a first direction (D1) 1009 of a periphery of a vertical three dimensional (3D) memory, such as taken along cut-line B-B′ in FIG. 7A.

As shown in FIG. 10A, the first conductive material 1077, forming the horizontally oriented access lines, can cascade down the multiple levels 1013-1 (L-1), 1013-2 (L-2), . . . , 1013-N (L-N) of a staircase structure (geometry) 1092 on a periphery 1090 of the array of the vertical three dimensional (3D) memory and, undesirably, electrically couple the horizontally oriented access lines 1077 on each level. As described above, herein, in some embodiments, one or more dielectric materials/layers, e.g., a first dielectric material 1039, can separate each level of the horizontally oriented access devices and horizontally oriented storage nodes of on the periphery 1090 of the vertical three dimensional (3D) memory. Along cut-line B-B′, as shown in FIG. 7A, the horizontal access lines 1077 flow crosswise, left to right in the plane of the drawing sheet, over channel regions of silicon (Si) material 1032-1, 1032-2, . . . , 1032-N to the periphery 1090 where the staircase structure 1092 can be located. At the staircase structure 1092, during a formation of the continuous horizontal access lines 1077 in the semiconductor fabrication process, a deposition of the first conductive material 1077 to form the continuous horizontally oriented access lines can cascade between levels, 1013-1 (L-1), 1013-2 (L-2), . . . , 1013-N (L-N), to undesirably, electrically couple the horizontally oriented access lines 1077 between each level, 1013-1 (L-1), 1013-2 (L-2), . . . , 1013-N (L-N). According to embodiments, the example shown in FIG. 10A illustrates a mask material 1035 that can be deposited over first conductive material 1077 which has horizontally cascaded and is electrically connected between levels 1013-1 (L-1), 1013-2 (L-2), . . . , 1013-N (L-N), forming that which makes up the horizontally oriented access lines 1077. The mask material 1035 may be a first dielectric material 1039, or other suitable mask material, and may fill the staircase structure 1092 in the periphery 1090 and be planarized, using chemical mechanical planarization (CMP) or other suitable technique, as shown in FIG. 10A.

FIG. 10B illustrates an example method, at another stage of a semiconductor fabrication process, for forming bifurcated access line contacts in vertical three dimensional (3D) memory, in accordance with a number of embodiments of the present disclosure. As shown in FIG. 10B, the method can include patterning the mask layer 1035 over the staircase structure 1092 and forming a plurality of spaced, vertical openings 1078-1, 1078-2, . . . , 1078-N (individually or collectively referred to as spaced, vertical openings 1078) through the mask layer 1035 to the conductive material 1077 on each level, 1013-1 (L-1), 1013-2 (L-2), . . . , 1013-N (L-N) of the staircase structure 1092. In some embodiments, the plurality of spaced, vertical openings (e.g., spaced second vertical openings) 1078 can be formed using a selective etch process to stop upon and expose a portion the first conductive material 1077 that forms the horizontally oriented access lines on each level, 1013-1 (L-1), 1013-2 (L-2), . . . , 1013-N (L-N), of the staircase structure 1092.

FIG. 10C illustrates an example method, at another stage of a semiconductor fabrication process, for forming bifurcated access line contacts, to each separate level 1013-1 (L-1), 1013-2 (L-2), . . . , 1013-N (L-N), in vertical three dimensional (3D) memory, in accordance with a number of embodiments of the present disclosure. As shown in FIG. 10C, the method can include conformally depositing a selectively etchable dielectric material 1080 in the plurality of spaced, vertical openings 1078. In some embodiments the selectively etchable dielectric material 1080 may be conformally deposited using a chemical vapor deposition (CVD) processing technique, an atomic layer deposition (ALD) processing technique, or other suitable process to achieve conformal deposition within the plurality of spaced, vertical openings 1078.

In some embodiments, the dielectric material 1080 can be a sacrificial material. In some embodiments, the dielectric material 1080 can be formed using a nitride (N) material, e.g., Si₃N₄, or SiCN. The method can further include depositing a different dielectric material, e.g., the first dielectric material 1039 to fill a remaining portion of each of the plurality of spaced, vertical openings 1078 to an upper surface. A different dielectric material 1039 is used so that the conformally deposited dielectric material 1080 remains selectively etchable, e.g., independently removable in a subsequent process step.

FIG. 10D illustrates an example method, at another stage of a semiconductor fabrication process, for forming bifurcated access line contacts, to each level, 1013-1 (L-1), 1013-2 (L-2), . . . , 1013-N (L-N), in vertical three dimensional (3D) memory, in accordance with a number of embodiments of the present disclosure. As shown in FIG. 10D, the method can include forming a plurality of spaced, vertical openings 1082-1, 1082-2, . . . , 1082-N (individually or collectively referred to as 1082) through the different dielectric material, e.g., first dielectric material 1039, and the dielectric, e.g., sacrificial material 1080, and a portion of the conductive material 1077, interior to the conformally deposited sacrificial material 1080, to separate the first conductive material 1077 and bifurcate the sacrificial material 1080 on each level, 1013-1 (L-1), 1013-2 (L-2), . . . , 1013-N (L-N), of the staircase structure 1092. In some embodiments, a mask material 1035 can be patterned and the plurality of spaced, vertical openings 1082 through the different dielectric material, e.g., first dielectric material 1039, and the dielectric, e.g., sacrificial material 1080, may be selectively etched to remove the first dielectric material 1039 and the sacrificial material 1080. Then a sequential etch selective to those materials may be used to selectively remove the portion of the first conductive material 1077. Each of the plurality of spaced, vertical openings (e.g., spaced, third vertical openings) 1082 can be formed using an etching process that exposes a portion of the first dielectric material 1039, entirely separating the first conductive material 1077 at each level, 1013-1 (L-1), 1013-2 (L-2), . . . , 1013-N (L-N), of the staircase structure 1092 such that the horizontally oriented access lines no longer continuously, electrically cascade between levels, 1013-1 (L-1), 1013-2 (L-2), . . . , 1013-N (L-N) down the staircase structure 1092.

The spaced, vertical openings 1082 can separate the horizontally oriented access lines 1077 of each level of the staircase structure 1092 from the horizontally oriented access lines 1077 of the different levels of the staircase structure 1092. This allows the horizontally oriented access lines 1077 of each level of the staircase structure 1092 to be activated separately since the horizontally oriented access lines 1077 of one level is no longer electrically connected to the horizontally oriented access lines 1077 of a different level, 1013-1 (L-1), 1013-2 (L-2), . . . , 1013-N (L-N), of the staircase structure 1092.

FIG. 10E illustrates an example method, at another stage of a semiconductor fabrication process, for forming bifurcated access line contacts in vertical three dimensional (3D) memory, in accordance with a number of embodiments of the present disclosure. As shown in FIG. 10E, the method can include depositing a dielectric material, e.g., first dielectric material, 1039 to fill the plurality of spaced, vertical openings 1082 on each level of the staircase structure 1092 to electrically isolate and separate the horizontally oriented access lines 1077 on each level, 1013-1 (L-1), 1013-2 (L-2), . . . , 1013-N (L-N), of the vertical 3D memory.

FIG. 10F illustrates an example method, at another stage of a semiconductor fabrication process, for forming bifurcated access line contacts in vertical three dimensional (3D) memory, in accordance with a number of embodiments of the present disclosure. As shown in FIG. 10F, the method can include selectively removing the sacrificial material 1080 on each level, 1013-1 (L-1), 1013-2 (L-2), . . . , 1013-N (L-N), of the staircase structure 1092. Selectively removing the sacrificial material 1080 forms vertical openings 1084. A selective etch process can be used to remove the sacrificial material 1080 and form vertical openings 1084. In some embodiments, each level, 1013-1 (L-1), 1013-2 (L-2), . . . , 1013-N (L-N), of the staircase structure 1092 can include two vertical openings 1084.

FIG. 10G illustrates an example method, at another stage of a semiconductor fabrication process, for forming bifurcated access line contacts in vertical three dimensional (3D) memory, in accordance with a number of embodiments of the present disclosure. As shown in FIG. 10G, the method can include depositing a second conductive material 1086 to separately form electrical contact with the conductive material 1077, which forms the horizontally oriented access lines 1077, on each level, 1013-(L-1), 1013-2 (L-2), . . . , 1013-N (L-N), of the staircase structure 1092. The deposition of the second conductive material 1086 can form separate vertically oriented, electrical connections (e.g., bifurcated access line contacts) 1086 that are connected to a different one of a plurality of horizontally oriented access lines 1077 on each level, 1013-1 (L-1), 1013-2 (L-2), . . . , 1013-N (L-N), of the staircase structure 1092 in the vertical 3D memory. In some embodiments, the second conductive material 1086 forming each of the separate vertical connections 1086 can be a tungsten (W) material. In other embodiments, the second conductive material 1086 can be a titanium metal composition material, a doped silicon material, or other selectable conductor. Embodiments are not limited to the examples herein.

In some embodiments, one or more of each separate vertical electrical connection 1086 can contact each of the plurality of horizontally oriented access lines 1077, wherein each of the separate vertical electrical connections 1086 can contact that horizontally oriented access lines 1077 at one or more separate locations, e.g., 1077-1A and 1077-1B, 1077- 2A and 1077-2B, . . . , 1077-NA and 1077-NB. 1077-(N+1) A represents one of the locations an electrical connection 1086 can contact 1077-(N+1). For example, as shown in FIG. 10G, the two separate vertical electrical connections 1086-A and 1086-B can contact each of the horizontally oriented access lines 1077 at separate locations, e.g., 1077-2A and 1077-2B.

FIG. 10H illustrates an example method, at another stage of a semiconductor fabrication process, for forming bifurcated access line contacts in vertical three dimensional (3D) memory, in accordance with a number of embodiments of the present disclosure. As shown in FIG. 10H, a mask 1037 can be formed and patterned to form electrical contact lines 1088 to more than one of the vertical electrical connections 1086, e.g., 1086-A and 1086-B, such that two separate vertical electrical connections 1086-A and 1086-B can be electrically connected a same conductive, electrical contact line, e.g., 1088-2 serving a continuous, gate all around, horizontally oriented access line, e.g., 1077-2, on a particular level, e.g., L-2, at the staircase structure 1092 of the vertical 3D memory. For example, two separate vertical connections 1086-A and 1086-B coupled to a same conductive electrical contact line 1088-2 can be coupled to a horizontally oriented access line 1077-2 at two separate locations. In one embodiment, a first location 1086-A of the two separate locations can provide electrical connection at an upper portion of a given horizontally oriented access line 1077-2 and a second location 1086-2 of the two separate locations can provide electrical connection at a lower portion of the same particular horizontally oriented access line 1077-2.

Further, as illustrated in FIG. 10H, one of the two vertical connections 1086-A coupled to a respective conductive line 1088 can be coupled to one level of the staircase structure 1092 and the other of the two vertical connections 1086-B can be coupled to a same horizontally oriented access line 1077-2 at a different level of the staircase structure 1092. As mentioned above, in some embodiments, the conductive lines 1088 can be formed by depositing a second mask material 1037 the staircase structure and the vertical connections 1086, and patterning and etching the second mask material 1037. The conductive lines 1088 can then be formed in the portions of the second mask material 1037 that was patterned and etched.

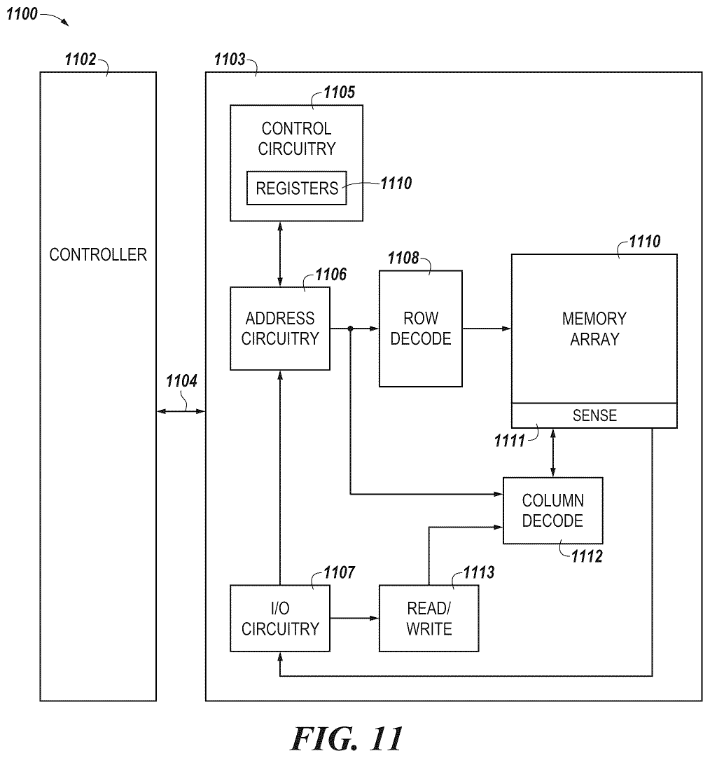

FIG. 11 is a block diagram of an apparatus in the form of a computing system 1100 including a memory device 1103 in accordance with a number of embodiments of the present disclosure. As used herein, a memory device 1103, a memory array 1110, and/or a host 1102, for example, might also be separately considered an “apparatus.” According to embodiments, the memory device 1103 may comprise at least one memory array 1110 with a memory cell formed having a digit line and body contact, according to the embodiments described herein.

In this example, system 1100 includes a host 1102 coupled to memory device 1103 via an interface 1104. The computing system 1100 can be a personal laptop computer, a desktop computer, a digital camera, a mobile telephone, a memory card reader, or an Internet-of-Things (IoT) enabled device, among various other types of systems. Host 1102 can include a number of processing resources (e.g., one or more processors, microprocessors, or some other type of controlling circuitry) capable of accessing memory 1103. The system 1100 can include separate integrated circuits, or both the host 1102 and the memory device 1103 can be on the same integrated circuit. For example, the host 1102 may be a system controller of a memory system comprising multiple memory devices 1103, with the system controller 1105 providing access to the respective memory devices 1103 by another processing resource such as a central processing unit (CPU).

In the example shown in FIG. 11, the host 1102 is responsible for executing an operating system (OS) and/or various applications (e.g., processes) that can be loaded thereto (e.g., from memory device 1103 via controller 1105). The OS and/or various applications can be loaded from the memory device 1103 by providing access commands from the host 1102 to the memory device 1103 to access the data comprising the OS and/or the various applications. The host 1102 can also access data utilized by the OS and/or various applications by providing access commands to the memory device 1103 to retrieve said data utilized in the execution of the OS and/or the various applications.

For clarity, the system 1100 has been simplified to focus on features with particular relevance to the present disclosure. The memory array 1110 can be a DRAM array comprising at least one memory cell having a digit line and body contact formed according to the techniques described herein. For example, the memory array 1110 can be an unshielded DL 4F2 array such as a 3D-DRAM memory array. The array 1110 can comprise memory cells arranged in rows coupled by word lines (which may be referred to herein as access lines or select lines) and columns coupled by digit lines (which may be referred to herein as sense lines or data lines). Although a single array 1110 is shown in FIG. 11, embodiments are not so limited. For instance, memory device 1103 may include a number of arrays 1110 (e.g., a number of banks of DRAM cells).

The memory device 1103 includes address circuitry 1106 to latch address signals provided over an interface 1104. The interface can include, for example, a physical interface employing a suitable protocol (e.g., a data bus, an address bus, and a command bus, or a combined data/address/command bus). Such protocol may be custom or proprietary, or the interface 1104 may employ a standardized protocol, such as Peripheral Component Interconnect Express (PCIe), Gen-Z, CCIX, or the like. Address signals are received and decoded by a row decoder 1108 and a column decoder 1112 to access the memory array 1110. Data can be read from memory array 1110 by sensing voltage and/or current changes on the sense lines using sensing circuitry 1111. The sensing circuitry 1111 can comprise, for example, sense amplifiers that can read and latch a page (e.g., row) of data from the memory array 1110. The I/O circuitry 1107 can be used for bi-directional data communication with the host 1102 over the interface 1104. The read/write circuitry 1113 is used to write data to the memory array 1110 or read data from the memory array 1110. As an example, the circuitry 1113 can comprise various drivers, latch circuitry, etc.

Control circuitry 1105 decodes signals provided by the host 1102. The signals can be commands provided by the host 1102. These signals can include chip enable signals, write enable signals, and address latch signals that are used to control operations performed on the memory array 1110, including data read operations, data write operations, and data erase operations. In various embodiments, the control circuitry 1105 is responsible for executing instructions from the host 1102. The control circuitry 1105 can comprise a state machine, a sequencer, and/or some other type of control circuitry, which may be implemented in the form of hardware, firmware, or software, or any combination of the three. In some examples, the host 1102 can be a controller external to the memory device 1103. For example, the host 1102 can be a memory controller which is coupled to a processing resource of a computing device.

The term semiconductor can refer to, for example, a material, a wafer, or a substrate, and includes any base semiconductor structure. “Semiconductor” is to be understood as including silicon-on-sapphire (SOS) technology, silicon-on-insulator (SOI) technology, thin-film-transistor (TFT) technology, doped and undoped semiconductors, epitaxial silicon supported by a base semiconductor structure, as well as other semiconductor structures. Furthermore, when reference is made to a semiconductor in the preceding description, previous process steps may have been utilized to form regions/junctions in the base semiconductor structure, and the term semiconductor can include the underlying materials containing such regions/junctions.

The figures herein follow a numbering convention in which the first digit or digits correspond to the drawing figure number and the remaining digits identify an element or component in the drawing. Similar (e.g., the same) elements or components between different figures may be identified by the use of similar digits. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate the embodiments of the present disclosure and should not be taken in a limiting sense.

As used herein, “a number of” or a “quantity of” something can refer to one or more of such things. For example, a number of or a quantity of memory cells can refer to one or more memory cells. A “plurality” of something intends two or more. As used herein, multiple acts being performed concurrently refers to acts overlapping, at least in part, over a particular time period. As used herein, the term “coupled” may include electrically coupled, directly coupled, and/or directly connected with no intervening elements (e.g., by direct physical contact), indirectly coupled and/or connected with intervening elements, or wirelessly coupled. The term coupled may further include two or more elements that co-operate or interact with each other (e.g., as in a cause and effect relationship). An element coupled between two elements can be between the two elements and coupled to each of the two elements.

It should be recognized the term vertical accounts for variations from “exactly” vertical due to routine manufacturing, measuring, and/or assembly variations and that one of ordinary skill in the art would know what is meant by the term “perpendicular.” For example, the vertical can correspond to the z-direction. As used herein, when a particular element is “adjacent to” another element, the particular element can cover the other element, can be over the other element or lateral to the other element and/or can be in direct physical contact with the other element. Lateral to may refer to the horizontal direction (e.g., the y-direction or the x-direction) that may be perpendicular to the z-direction, for example.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

What is claimed is:

1. A method for forming arrays of vertically stacked memory cells, having horizontally oriented access devices and storage nodes, comprising:
forming alternating layers of silicon germanium (SiGe) material and silicon (Si) material to form a plurality of levels in a vertical stack;
forming a first vertical opening through the vertical stack and extending predominantly in the first horizontal direction to expose first vertical sidewalls in the stack;
selectively etching the silicon germanium (SiGe) layers and reducing a vertical thickness of the silicon (Si) layers to form a plurality of first horizontal openings, a first length (L1) from the first vertical opening;
forming gate all around (GAA) structures with a continuous first conductive material that runs a length of the first vertical opening in the first horizontal openings and cascades vertically in a third direction down the stack in a region on a periphery of the stack, having a staircase structure;
patterning a mask layer over the staircase structure;
forming a plurality of spaced, second vertical openings through the mask layer to the first conductive material on each level of the staircase structure;
conformally depositing a first, selectively etchable sacrificial material in the plurality of spaced, second vertical openings;
depositing a first dielectric material to fill a remaining portion of the plurality of spaced, second vertical openings;
forming a plurality of spaced, third vertical openings through the first dielectric material, the sacrificial material, and a portion of the first conductive material, interior to the conformally deposited sacrificial material to separate the first conductive material and bifurcate the sacrificial material on each level of the staircase structure;
depositing the first dielectric material to fill the plurality of spaced, third vertical openings on each level of the staircase structure;
selectively removing the sacrificial material on each level of the staircase structure; and
depositing a second conductive material to separately form electrical contact with the first conductive material on each level of the staircase structure.

2. The method of claim 1, further comprising removing a bottom portion of the vertical stack to form a second horizontal opening, wherein the bottom portion of the vertical stack includes a layer of silicon germanium (SiGe) material that is closer to the substrate than other layers of silicon germanium (SiGe) material, a layer of silicon (Si) material that is closer to the substrate than other layers of silicon (Si) material, or both.

3. The method of claim 2, further comprising depositing the first dielectric material to fill the second horizontal opening.

4. The method of claim 1, further comprising reducing the vertical thickness of each of the silicon (Si) layers to a range of 100 to 150 Angstroms (Å).

5. The method of claim 1, wherein forming a first vertical opening further comprises forming horizontally oriented access devices and horizontally oriented storage nodes at each level of the vertical stack to form the array of vertically stacked memory cells, each horizontally oriented access device having first source/drain regions and second source drain regions separated by channel regions, and gates formed fully around every surface of the channel regions as gate all around (GAA) structures on a gate dielectric material, and the second source/drain regions coupled to the horizontally oriented storage nodes.

6. The method of claim 5, wherein forming the horizontally oriented access devices and the horizontally oriented storage nodes at each level of the vertical stack further comprises:
forming a plurality of fourth vertical openings, having a first horizontal direction and a second horizontal direction, through the vertical stack, the fourth vertical openings extending predominantly in the second horizontal direction to form elongated vertical, pillar columns with second vertical sidewalls in the stack;
filling the plurality of fourth vertical openings with the first dielectric material;
before forming the GAA structures with the continuous first conductive material, conformally depositing a second dielectric material on exposed surfaces in the plurality of first horizontal openings;
depositing the first dielectric material to fill the plurality of first horizontal openings;
selectively etching the second dielectric material from the plurality of first horizontal openings a second length (L2) from the second vertical opening; and
filling a remaining portion of the first horizontal openings with the first conductive material to the periphery of the vertical stack.

7. The method of claim 1, further comprising forming each of the plurality of first vertical openings to a depth in a range of 0.5 to 1 micrometer.

8. The method of claim 1, further comprising forming each of the plurality of first vertical openings to have an aspect ratio in a range of 15-20.

9. The method of claim 1, further comprising using a same material to form the first dielectric material and the second dielectric material.

10. A method for forming arrays of vertically stacked memory cells, having horizontally oriented access devices and storage nodes, comprising:
forming alternating layers of a first semiconductor material and a second semiconductor material to form a plurality of levels in a vertical stack;
forming a first vertical opening through the vertical stack and extending predominantly in the first horizontal direction to expose first vertical sidewalls in the stack;
selectively etching the first semiconductor layers and reducing a vertical thickness of the second semiconductor layers to form a plurality of first horizontal openings, a first length (L1) from the first vertical opening;
forming gate all around (GAA) structures with a continuous access line material that runs a length of the first vertical opening in the first horizontal openings and cascades vertically in a third direction (D3) down the vertical stack in a region on the periphery of the stack, having a staircase structure;
forming a plurality of spaced, second vertical openings through a mask layer that is deposited on the staircase structure to the access line material on each level of the staircase structure;
conformally depositing a sacrificial material in the plurality of spaced, second vertical openings;
depositing a dielectric material to fill a remaining portion of the plurality of spaced, second vertical openings;
forming a plurality of spaced, third vertical openings through the dielectric material, the sacrificial material, and a portion of the access line material, interior to the conformally deposited sacrificial material to separate the access line material and bifurcate the sacrificial material on each level of the staircase structure;
depositing the dielectric material to fill the plurality of spaced, third vertical openings on each level of the staircase structure;
selectively removing the sacrificial material on each level of the staircase structure; and
depositing an access line contact material to separately form electrical contact with the access line material on each level of the staircase structure.

11. The method of claim 10, further comprising using a first material to form the first dielectric material and a second material to form the second dielectric material, wherein the first material is a different material than the second material.

12. The method of claim 10, further comprising forming the sacrificial material using a nitride (Ni) material.

13. The method of claim 10, wherein the second length is in a range between 130 to 170 nm.

14. A memory device, comprising:
an array of vertically stacked memory cells, having a plurality of levels, each level of the array having horizontally oriented access devices and horizontally storage nodes, comprising:
the horizontally oriented access devices having first source/drain regions and second source drain regions separated by channel regions, and gates opposing the channel regions formed fully around every surface of each of the channel regions as gate all around (GAA) structures on a gate dielectric material; and
the horizontally oriented storage nodes electrically coupled to the second source/drain regions of the horizontally oriented access devices;
a staircase structure at each level on a periphery of the array of vertically stacked memory cells; and
a plurality of separate vertical connections each connected to a different one of a plurality of horizontally oriented access lines formed with the GAA structures on each level of the array.

15. The memory device of claim 14, wherein each of the plurality of separate vertical connections are formed using a tungsten (W) material.

16. The memory device of claim 14, wherein one or more of the plurality of separate vertical connections contacts each of the plurality of horizontally oriented access lines.

17. The memory device of claim 14, wherein a first vertical connection contacts a respective horizontally oriented access line at a location above the respective horizontally oriented access line and a second vertical connection contacts the respective horizontally oriented access line at a location below the respective horizontally oriented access line.

18. The memory device of claim 14, wherein a first vertical connection contacts a respective horizontally oriented access line on a same level of the staircase structure as the respective horizontally oriented access line and a second vertical connection contacts the respective horizontally oriented access line on a different level of the staircase structure than the respective horizontally oriented access line.

19. The memory device of claim 14, wherein each level of the staircase structure is in contact with one or more of the vertical contacts.

20. The memory device of claim 19, wherein a first vertical contact of a first level of the staircase structure and a second vertical contact of a second level of the staircase structure are coupled to a same conductive line.
